(19) United States
(12) Patent Application Publication
(10) Pub. No.: US 2009/0267125 A1
(43) Pub. Date: Oct. 29, 2009

(54) SEMICONDUCTOR DEVICE AND METHOD OF MANUFACTURING THE SAME

(75) Inventors: Noriaki MIKASA, Tokyo (JP); Masahiro MIURA, Tokyo (JP); Hirotoshi SEKI, Tokyo (JP)

Correspondence Address: YOUNG & THOMPSON, 209 Madison Street, Suite 500, ALEXANDRIA, VA, 22314, US

(73) Assignee: ELPIDA MEMORY, INC., Tokyo (JP)

(21) Appl. No.: 12/235,936

(22) Filed: Sep. 23, 2008

(30) Foreign Application Priority Data
Sep. 28, 2007 (JP) 2007-255350
Dec. 21, 2007 (JP) 2007-330098
May 27, 2008 (JP) 2008-138156

(51) Int. Cl. H01L 27/108; H01L 21/8242

(52) U.S. Cl. 257/300; 438/241; 257/E27.084; 257/E21.646

(57) ABSTRACT

An isolation region comprises a step structure comprising a step surface that is perpendicular to a depth direction, an upper isolation region and a lower isolation region. An RC transistor is enclosed by the isolation region.

This application is based upon and claims the benefit of priority from Japanese Patent Application No. 2007-255350, filed on Sep. 28, 2007, No. 2007-330098, filed on Dec. 21, 2007, and No. 2008-138156, filed on May 27, 2008, the disclosure of which is incorporated herein in its entirety by reference.

### BACKGROUND OF THE INVENTION

1. Field of the Invention

The present invention relates to a semiconductor device and a method of manufacturing the semiconductor device.

2. Description of the Related Art

(1) Adjacent semiconductor elements have been insulated with an isolation region as miniaturization of semiconductor devices proceeds. An STI (Shallow Trench Isolation) structure has been used as an isolation region suitable for the miniaturization. The isolation region of the STI structure is formed by the following steps.

(a) A first SiO₂ film and a Si₃N₄ film are formed on a silicon substrate.

(b) A resist mask is formed by a photolithography technique.

(c) The first SiO₂ film, the Si₃N₄ film, and the silicon substrate are etched to a desired depth using the resist mask as a mask by means of anisotropic etching to form a trench in the silicon substrate.

(d) A thick second SiO₂ film is deposited all over a surface of the silicon substrate to fill the interior of the trench with the second SiO₂ film.

(e) The second SiO₂ film is removed by etching and a chemical mechanical polishing (CMP) method using the Si₃N₄ film as an etching stopper.

(f) The Si₃N₄ film and the first SiO₂ film are removed.

Here, even if the size of the isolation region is reduced as a result of the miniaturization, the isolation region is desirably filled with an insulating material to offer a stable insulating property. Thus, efforts have been made to develop methods of forming an isolation region with stable insulating property.

Japanese Patent Laid-Open No. 2000-183150 discloses a method of forming a trench for an isolation region, then forming an SOG (Spin On Glass) film under the trench, and subsequently forming a silicon oxide film on the SOG film using an HDP-CVD (High Density Plasma-Chemical Vapor Deposition) method.

Japanese Patent Laid-Open No. 2000-114362 discloses a method of forming a trench for an isolation region, then forming an SOG (Spin On Glass) film under the trench, and subsequently forming a silicon oxide film on the SOG film using a CVD (Chemical Vapor Deposition) method.

Japanese Patent Laid-Open No. 2005-294759 discloses a semiconductor device including a multistage trench structure made up of at least two stages of trenches with the width of the trenches decreasing in stages in a depth direction.

(2) On the other hand, to solve problems such as a decrease in threshold voltage and an increase in off current caused by a short channel effect resulting from a decrease in gate length, trench gate transistors have more often been used which include a trench formed in a semiconductor substrate and into which a gate electrode is filled. Japanese Patent Laid-Open Nos. hei 9-232535 and 2003-23150 disclose the trench gate transistor.

However, with a trench gate transistor of a simple structure, the formation of a high-performance transistor is difficult which offers as much on current as possible with a decrease in threshold voltage inhibited. Thus, as a trench gate transistor improved in this regard, a structure provided with a channel area in a side portion of the trench has been developed as disclosed in Japanese Patent Laid-Open No. 2007-158269. The improved trench gate transistor is hereinafter referred to as an RC (Recessed Channel) transistor.

A method of manufacturing a related semiconductor device including two RC transistors insulated from each other via an isolation region will be described below. FIG. 22 is a plan view of the semiconductor device including two diffusion layer areas (active areas) 101 formed on a semiconductor substrate (not shown in the drawings) such as silicon by doping of impurities. An isolation region 103 made up of an insulating film is located around the periphery of each of the diffusion layer areas 101. A gate trench is shown at 102. The diffusion layer areas 101, arranged on the opposite sides of the gate trench 102, function as impurity diffusion layers for a source and a drain areas of the transistor. In FIG. 2B, description of electrode lead-out wiring layer and the like is omitted. FIGS. 24A to 24C are sectional views of a cross section of the semiconductor device taken along line D-D′ in FIG. 2B, illustrating a manufacturing process. First, as shown in FIG. 24A, the isolation region 103 made up of a silicon oxide film is formed in a semiconductor substrate 100 using a well-known STI (Shallow Trench Isolation). The diffusion layer areas 101 are partitioned by the isolation region 103.

Then, as shown in a plan view in FIG. 23, a mask layer 104 is formed using a silicon nitride film or the like which is patterned such that a portion of the substrate in which a gate electrode 102 is to be formed is open.

Then, as shown in FIG. 24B, the silicon is etched by a dry etching method to form a trench 105 in the diffusion layer area 101. The mask layer 104 is then removed. At this time, a side wall portion of the isolation region 103 is inclined at an angle of about 5 to 10° to a vertical direction. Thus, an upper part of the isolation region 103 functions as a mask for the silicon etching. A thin film-like silicon layer 106 thus remains in contact with a side surface of the isolation region 103. The thin film-like silicon layer 106 functions as a channel area of the transistor.

For a part of the isolation region 103 which is not covered with the mask layer 104, during the etching for forming the trench 105, a surface of the insulating film (silicon oxide film) is slightly scraped with no trench formed in this part.

Then, as shown in FIG. 24C, a gate insulating film 107 is formed, and a conductive film 108 such as polycrystalline silicon is buried in the trench portion.

Subsequently, the buried conductive film 108 is patterned such that it has the planar shape of the gate electrode 102 as shown in FIG. 22. Then, ions of N- or P-type impurities are implanted into the diffusion layer area 101 to form the impurity diffusion layers for the source and the drain areas. A semiconductor device including the isolation region and the two RC transistors is thus formed.

(1) However, in the anisotropic etching in step (c) for the isolation region STI, an inner wall of the isolation region has a predetermined gradient of about 5 to 10°. Since the gradient of the inner wall of the trench is within a given range, the width of the isolation region is determined by the width of the isolation region on the surface of the semiconductor substrate and the depth from the surface of the semiconductor substrate. As a result, it is conventionally difficult to freely control the width of the isolation region depending on the depth in order to cope with miniaturization and various device designs. In particular, if the two semiconductor elements are isolatively separated from each other via the isolation region, the isolation region of the general STI structure as described above fails to enable variation of the distance between adjacent semiconductor elements in the depth direction.

Such a problem also occurs in the isolation regions described in Japanese Patent Laid-Open Nos. 2000-183150 and 2000-114362 and each including an inner wall with a gradient of a predetermined angle. For the isolation regions in Japanese Patent Laid-Open Nos. 2000-183150 and 2000-114362, the SOG film is buried under the trench. Unexpected fixed charges may be present in the SOG film. Thus, for example, if the isolation region contacts the RC transistor, the fixed charges vary the threshold voltage of the RC transistor.

Japanese Patent Laid-Open No. 2005-294759 discloses a method of sequentially forming the isolation region of the multistage structure using the following steps (by way of example, the following steps provide a three-stage isolation region).

(A) A step of forming a first opening,

(B) a step of forming a side wall on a side surface of the first opening,

(C) a step of etching the bottom of the first opening using the side wall as a mask to form a second opening,

(D) a step of forming a side wall on a side surface of the second opening,

(E) a step of etching the bottom of the second opening using the side wall as a mask to form a third opening, and

(F) a step of, after forming the third opening, filling the interior of a trench made up of the first to third openings with an insulating material.

The method in Japanese Patent Laid-Open No. 2005-294759 forms the trench in three stages to form the isolation region made up of a thick insulating film to resist high voltages. With this method, the aspect ratio of the trench increases after the formation of the third opening. Thus, the filling of the insulating material results in a void in the trench. When a semiconductor element is formed adjacent to the isolation region, the void may be exposed. This is significant when the semiconductor element is miniaturized.

Thus, an isolation region has been required which avoids using the SOG film to prevent a possible void from being exposed during the formation of the semiconductor element.

(2) This problem is more serious in a semiconductor device including an RC transistor. That is, with this manufacturing method, as shown in FIG. 24B, the channel area is formed by dry-etching the silicon to leave the part of the silicon layer 106 that is in contact with the isolation region 103, as a thin film. The inclination (taper angle) of a side surface of the isolation region to a vertical direction is a small angle of about 5 to 10°. Thus, the film thickness, height, shape, or the like of the silicon layer (106) may significantly vary even a slight change in the taper angle of the isolation region is caused by a variation during manufacture. Consequently, in this case, the electrical properties of the RC transistor finally formed may disadvantageously vary significantly.

Furthermore, although the insulating material can be uniformly filled in even a narrow lower trench in the SOG film as described in Japanese Patent Laid-Open Nos. 2000-183150 and 2000-114362, the threshold voltage (Vₜ) of the RC transistor may disadvantageously be varied by fixed charges present in the SOG film (organic film). That is, charges of a conductivity type opposite to that of fixed charges are induced in the channel area (active area). When a voltage is applied to the gate electrode of the RC transistor, the induced charges act to reduce the voltage. Thus, controlling the gate voltage of the RC transistor and thus the control of Vₜ is difficult. In particular, since the amount of fixed charges varies according to the configuration of the SOG film, the rate at which the gate voltage is reduced varies among the RC transistors. This makes controlling Vₜ more difficult. This problem does not occur in a planar transistor having a channel area formed on a surface portion of the semiconductor substrate but is peculiar to the use of the RC transistor.

Moreover, with the method disclosed in Japanese Patent Laid-Open No. 2005-294759, a void may occur in the isolation region. The void occurring in the isolation region is exposed in a process step (etching or the like during the formation of the semiconductor element) after formation of the isolation region. During deposition of the conductive material for the semiconductor element, the void may be filled with the conductive material to significantly degrade the insulating property of the isolation region.

### SUMMARY OF THE INVENTION

The present invention seeks to solve one or more of the above problems, or to improve upon those problems at least in part.

In the first embodiment, there is provided a semiconductor device comprising a field effect transistor comprising:

a second semiconductor area extending in a predetermined direction; a gate electrode buried in an intermediate portion of the second semiconductor area in the predetermined direction and extending upward from the second semiconductor area;

a recess portion constituting the intermediate portion of the second semiconductor area and includinci side portions located opposite to each side surface of the gate electrode buried in the recess portion that are parallel to the predetermined direction;

third semiconductor areas positioned on both sides in the second semiconductor area sandwiching the recess portion in the predetermined direction;

first semiconductor areas formed on the third semiconductor areas and positioned on both sides, in the predetermined direction, sandwiching the portion of the gate electrode which extends upward from the second semiconductor area;

a gate insulating film formed between the gate electrode and both the first and second semiconductor areas; and

impurity diffusion layers for a source and a drain areas formed in the first or third semiconductor areas;

wherein top surfaces of the side portions of the recess portion are the same level as a top surface of an end portion of the second semiconductor area in the predetermined direction.

In the second embodiment, there is provided a semiconductor device comprising an isolation region comprising:

a step structure including a step surface that is perpendicular to a depth direction;

an upper isolation region located above the step surface; and

a lower isolation region located below the step surface,

wherein a cross sectional area of the upper isolation region which is perpendicular to the depth direction is larger than a cross sectional area of the lower isolation region which is perpendicular to the depth direction.

In the third embodiment, there is provided a method of manufacturing a semiconductor device comprising an isolation region including a step structure including a step surface that is perpendicular to a depth direction, the method comprising:

(1) forming an upper opening in a semiconductor substrate;

(2) forming an insulating film on a side wall of the upper opening;

(3) forming a lower opening under the upper opening and forming the step surface under the insulating film by etching an interior of the upper opening using the insulating film as a mask;

(4) filling an insulating material into the lower opening by a CVD method or an HDP-CVD method to form a lower isolation region; and

(5) filling an insulating material into the upper opening by the HDP-CVD method to form an upper isolation region.

The first embodiment can provide a semiconductor device comprising an isolation region of a two-stage structure to allow the sectional area of the isolation region to be freely controlled according to the depth and to allow miniaturization and various device designs to be achieved.

The second embodiment can provide a semiconductor device comprising an RC transistor comprising a channel area with a top surface constituting a step surface to prevent a possible variation in the properties of the channel area.

The third embodiment can provide a method of manufacturing a semiconductor device comprising an isolation region of a two-stage structure to allow the sectional area of the isolation region to be freely controlled according to the depth and to allow miniaturization and various device designs to be achieved.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a diagram showing a semiconductor device according to a third exemplary embodiment;

FIG. 2A is a diagram showing the semiconductor device according to the third exemplary embodiment;

FIG. 2B is a diagram showing the semiconductor device according to the third exemplary embodiment;

FIG. 3 is a diagram showing a step of a method of manufacturing the semiconductor device according to the third exemplary embodiment;

FIG. 4A is a diagram showing a step of the method of manufacturing the semiconductor device according to the third exemplary embodiment;

FIG. 4B is a diagram showing a step of the method of manufacturing the semiconductor device according to the third exemplary embodiment;

FIG. 5A is a diagram showing a step of the method of manufacturing the semiconductor device according to the third exemplary embodiment;

FIG. 5B is a diagram showing a step of the method of manufacturing the semiconductor device according to the third exemplary embodiment;

FIG. 6A is a diagram showing a step of the method of manufacturing the semiconductor device according to the third exemplary embodiment;

FIG. 6B is a diagram showing a step of the method of manufacturing the semiconductor device according to the third exemplary embodiment;

FIG. 7A is a diagram showing a step of the method of manufacturing the semiconductor device according to the third exemplary embodiment;

FIG. 7B is a diagram showing a step of the method of manufacturing the semiconductor device according to the third exemplary embodiment;

FIG. 7C is a diagram showing a step of the method of manufacturing the semiconductor device according to the third exemplary embodiment;

FIG. 7D is a diagram showing a step of the method of manufacturing the semiconductor device according to the third exemplary embodiment;

FIG. 8A is a diagram showing a step of the method of manufacturing the semiconductor device according to the third exemplary embodiment;

FIG. 8B is a diagram showing a step of the method of manufacturing the semiconductor device according to the third exemplary embodiment;

FIG. 8C is a diagram showing a step of the method of manufacturing the semiconductor device according to the third exemplary embodiment;

FIG. 8D is a diagram showing a step of the method of manufacturing the semiconductor device according to the third exemplary embodiment;

FIG. 9A is a diagram showing a step of the method of manufacturing the semiconductor device according to the third exemplary embodiment;

FIG. 9B is a diagram showing a step of the method of manufacturing the semiconductor device according to the third exemplary embodiment;

FIG. 9C is a diagram showing a step of the method of manufacturing the semiconductor device according to the third exemplary embodiment;

FIG. 10 is a diagram showing a step of the method of manufacturing the semiconductor device according to the third exemplary embodiment;

FIG. 11A is a diagram showing a step of the method of manufacturing the semiconductor device according to the third exemplary embodiment;

FIG. 11B is a diagram showing a step of the method of manufacturing the semiconductor device according to the third exemplary embodiment;

FIG. 12A is a diagram showing a step of the method of manufacturing the semiconductor device according to the third exemplary embodiment;

FIG. 12B is a diagram showing a step of the method of manufacturing the semiconductor device according to the third exemplary embodiment;

FIG. 12C is a diagram showing a step of the method of manufacturing the semiconductor device according to the third exemplary embodiment;

FIG. 13A is a diagram showing a step of the method of manufacturing the semiconductor device according to the third exemplary embodiment;

FIG. 13B is a diagram showing a step of the method of manufacturing the semiconductor device according to the third exemplary embodiment;

FIG. 14A is a diagram showing a step of the method of manufacturing the semiconductor device according to the third exemplary embodiment;

FIG. 14B is a diagram showing a step of the method of manufacturing the semiconductor device according to the third exemplary embodiment;

FIG. 15 is a diagram showing a step of the method of manufacturing the semiconductor device according to the third exemplary embodiment;

FIG. 16A is a diagram showing a step of the method of manufacturing the semiconductor device according to the third exemplary embodiment;

FIG. 16B is a diagram showing a step of the method of manufacturing the semiconductor device according to the third exemplary embodiment;

FIG. 16C is a diagram showing a step of the method of manufacturing the semiconductor device according to the third exemplary embodiment;

FIG. 17A is a diagram showing a step of the method of manufacturing the semiconductor device according to the third exemplary embodiment;

FIG. 17B is a diagram showing a step of the method of manufacturing the semiconductor device according to the third exemplary embodiment;

FIG. 18A is a diagram showing a step of a method of manufacturing a semiconductor device according to a fourth exemplary embodiment;

FIG. 18B is a diagram showing a step of the method of manufacturing the semiconductor device according to the fourth exemplary embodiment;

FIG. 19A is a diagram showing a step of the method of manufacturing the semiconductor device according to the fourth exemplary embodiment;

FIG. 19B is a diagram showing a step of the method of manufacturing the semiconductor device according to the fourth exemplary embodiment;

FIG. 20 is a diagram showing a semiconductor device according to a fifth exemplary embodiment;

FIG. 21 is a diagram showing the semiconductor device according to the fifth exemplary embodiment;

FIG. 22 is a diagram showing a step of a related method of manufacturing a semiconductor device;

FIG. 23 is a diagram showing a step of the related method of manufacturing the semiconductor device;

FIG. 24A is a diagram showing a step of the related method of manufacturing the semiconductor device;

FIG. 24B is a diagram showing a step of the related method of manufacturing the semiconductor device;

FIG. 24C is a diagram showing a step of the related method of manufacturing the semiconductor device;

FIG. 25A is a diagram showing a semiconductor device according to a first exemplary embodiment;

FIG. 25B is a diagram showing the semiconductor device according to the first exemplary embodiment;

FIG. 26 is a diagram showing a step of a method of manufacturing a semiconductor device according to a second exemplary embodiment;

FIG. 27 is a diagram showing a step of the method of manufacturing the semiconductor device according to the second exemplary embodiment;

FIG. 28 is a diagram showing a step of the method of manufacturing the semiconductor device according to the second exemplary embodiment;

FIG. 29 is a diagram showing a step of the method of manufacturing the semiconductor device according to the second exemplary embodiment;

FIG. 30 is a diagram showing a step of the method of manufacturing the semiconductor device according to the second exemplary embodiment;

FIG. 31 is a diagram showing a step of the method of manufacturing the semiconductor device according to the second exemplary embodiment;

FIG. 32 is a diagram showing a step of the method of manufacturing the semiconductor device according to the second exemplary embodiment;

FIG. 33 is a diagram showing a step of a method of manufacturing a semiconductor device according to a sixth exemplary embodiment;

FIG. 34 is a diagram showing a step of the method of manufacturing the semiconductor device according to the sixth exemplary embodiment;

FIG. 35 is a diagram showing a step of the method of manufacturing the semiconductor device according to the sixth exemplary embodiment;

FIG. 36 is a diagram showing a step of the method of manufacturing the semiconductor device according to the sixth exemplary embodiment;

FIG. 37 is a diagram showing a step of the method of manufacturing the semiconductor device according to the sixth exemplary embodiment;

FIG. 38 is a diagram showing a step of the method of manufacturing the semiconductor device according to the sixth exemplary embodiment;

FIG. 39 is a diagram showing a step of the method of manufacturing the semiconductor device according to the sixth exemplary embodiment;

FIG. 40 is a diagram showing a step of a method of manufacturing a variation of the semiconductor device according to the sixth exemplary embodiment;

FIG. 41A is a diagram showing a step of a method of manufacturing a variation of the semiconductor device according to the third exemplary embodiment;

FIG. 41B is a diagram showing a step of the method of manufacturing the variation of the semiconductor device according to the third exemplary embodiment;

FIG. 42A is a diagram showing a step of a method of manufacturing a variation of the semiconductor device according to the third exemplary embodiment; and

FIG. 42B is a diagram showing a step of the method of manufacturing the variation of the semiconductor device according to the third exemplary embodiment.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

In exemplary embodiments described below, the semiconductor device comprises a transistor of an N channel type. However, the transistor may be of a P channel type as illustrated below.

### First Exemplary Embodiment

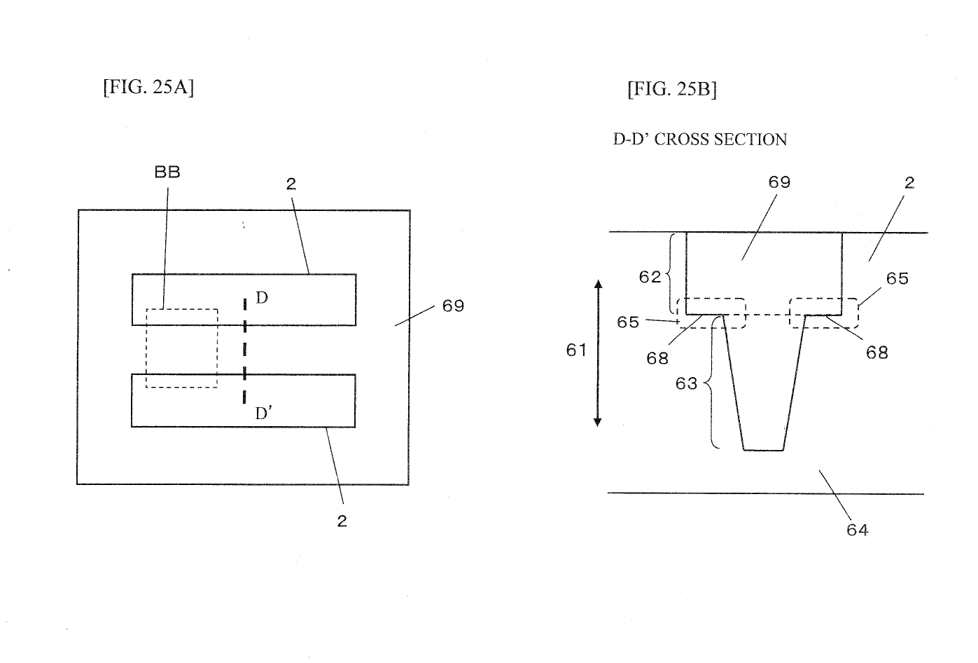

The first exemplary embodiment relates to a semiconductor device including an isolation region. FIG. 25A is a top view showing an example of the semiconductor device. FIG. 25B is a sectional view of the semiconductor device taken along line D-D′ in FIG. 25A. In FIG. 25A, an active area 2 is formed in the semiconductor substrate. An isolation region 69 is formed so as to surround the active area. The isolation region 69 comprises a step structure 65 including a step surface 68 that is perpendicular to a depth direction 61 of a semiconductor substrate 64.

The term “step structure” as used herein refers to, if the sectional area (the area of a surface perpendicular to the depth direction) of the isolation region changes discontinuously, for example, in the depth direction of an area BB (arbitrarily defined area) shown in FIG. 25A, a step-like structure formed in the boundary portion between a portion with a large sectional area and a portion with a small sectional area.

The isolation region 69 is composed of an upper isolation region 62 and a lower isolation region 63. The lower isolation region 63 is formed under the upper isolation region 62 in contact with the upper isolation region 62. The upper isolation region 62 is composed of a part of the isolation region located over the step surface 68. In FIG. 25B, the upper isolation region 62 is illustrated by the part of the isolation region 69 located over the step surface 68 and a dotted line. The lower isolation region 63 is composed of a part of the isolation region located under the step surface 68. In FIG. 25B, the lower isolation region 63 is illustrated by the part of the isolation region 69 located under the step surface 68 and a dotted line.

The semiconductor device according to the first exemplary embodiment includes the step surface. The sectional area of a cross section perpendicular to the depth direction changes discontinuously between the upper isolation region 62 and the lower isolation region 63 at the time of cutting across the step surface. Thus, the sectional area of the cross section of the upper isolation region 62 perpendicular to the depth direction is larger than that of the cross section of the lower isolation region 63 perpendicular to the depth direction.

In the upper and lower isolation regions, the sectional area may or may not vary on the depth direction. However, in the lower isolation region, the sectional area desirably decreases with increasing depth. If the sectional area varies in the depth direction in each of the upper and lower isolation regions, the expression “the sectional area of a cross section of the upper isolation region perpendicular to the depth direction is larger than that of a cross section of the lower isolation region perpendicular to the depth direction” means that the minimum value of the sectional area of the upper isolation region is larger than the maximum value of the sectional area of the lower isolation region.

The angle of the gradient of the side wall of each of the upper and lower isolation regions is not particularly limited. However, the side wall of the upper isolation region preferably extends vertically or almost vertically. The side wall of the lower isolation region is preferably inclined so that the sectional area of the side wall of the lower isolation region decreases with increasing depth.

A material forming the upper and lower isolation regions is not particularly limited provided that the material offers an insulating property. The upper and lower isolation regions may be composed of the same material or different materials. Furthermore, each of the upper and lower isolation regions need not entirely be composed of the same material but may be composed of a plurality of areas made up of different materials. Preferably, the upper isolation region contains silicon oxide, and the lower isolation region contains at least silicon nitride. Moreover, the lower isolation region may partly include a void provided that the void is prevented from being exposed from the surface of the lower isolation region when the area is subjected to etching or the like during a step following the formation of the isolation region.

According to the first exemplary embodiment, the isolation region thus includes the step structure, so that the sectional area of the lower isolation region can be freely controlled regardless of the sectional area of the upper isolation region, by controlling the width of the step surface 68. In particular, the sectional area, width, and aspect ration of the lower isolation region 63 can be freely controlled according to the depth. This allows miniaturization to be effectively achieved.

Furthermore, the isolation region according to the first exemplary embodiment is applicable as an isolation region offering an excellent insulating property even between semiconductor elements with different widths in the depth direction. This allows various device designs to be effectively achieved.

Moreover, the insulating property of the entire isolation region can be effectively controlled by filling the upper and lower isolation regions with the insulating material by different methods and under different conditions according to the properties of the upper and lower isolation regions. In particular, even when the lower isolation region has a high aspect ratio and a small width as a result of miniaturization, the insulating material can be stably and uniformly filled by using a deposition method suitable for deposition in narrow openings. Typical examples of such a deposition method include the CVD method and the HDP-CVD method. Examples of the insulating material include a silicon nitride film formed by the CVD method and a laminate film of a silicon oxide film and a silicon nitride film. A void-containing silicon oxide formed by the HDP-CVD method may also be used.

Even an upper isolation region with a relatively large sectional area can be stably and uniformly filled with the insulating material using a deposition method suitable for deposition in wide openings. A typical example of such a deposition method is the HDP-CVD method. An example of the insulating material is silicon oxide.

### Second Exemplary Embodiment

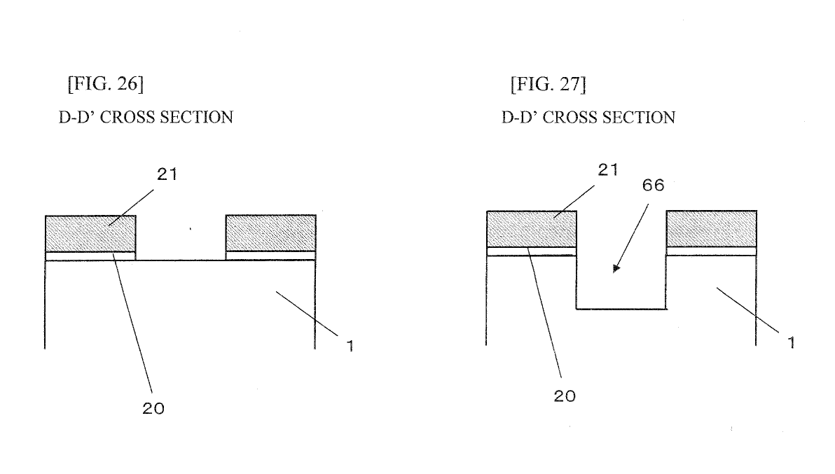

The present exemplary embodiment relates to a method of manufacturing a semiconductor device including an isolation region. FIGS. 26 to 31 are sectional views illustrating an example of the method of manufacturing the semiconductor device according to the second exemplary embodiment.

First, as specifically illustrated in FIG. 26, a silicon oxide film 20 is formed on a semiconductor substrate 1 by means of a thermal oxidation method or the like. A silicon nitride film (Si₃N₄) 21 is subsequently formed on the silicon oxide film. Then, the silicon oxide film 20 and the silicon nitride film (Si₃N₄) 21 are patterned using a dry etching method so as to form an opening in an area in which an upper opening is to be formed. The patterning enables a desired shape to be formed using a photo resist film (not illustrated in the drawings).

Then, as illustrated in FIG. 27, the silicon is dry-etched to form an upper opening 66 in an area of the semiconductor substrate 1 which is not covered with the silicon nitride film (Si₃N₄) 21 (step (1)). Specific manufacturing conditions for the dry etching include, for example, the use of gas containing a mixture of chloride (Cl₂), hydrogen bromide (HBr), oxygen (O₂), and the like, and an atmosphere with a pressure of 10 to 50 mTorr. In this case, the angle (taper angle) of the side wall of the upper opening 66 to the vertical direction can be adjusted by varying the flow rate of the etching gas or the like. However, the side wall is desirably formed to be perpendicular to the vertical direction in order to controllably form a step surface 68 described below.

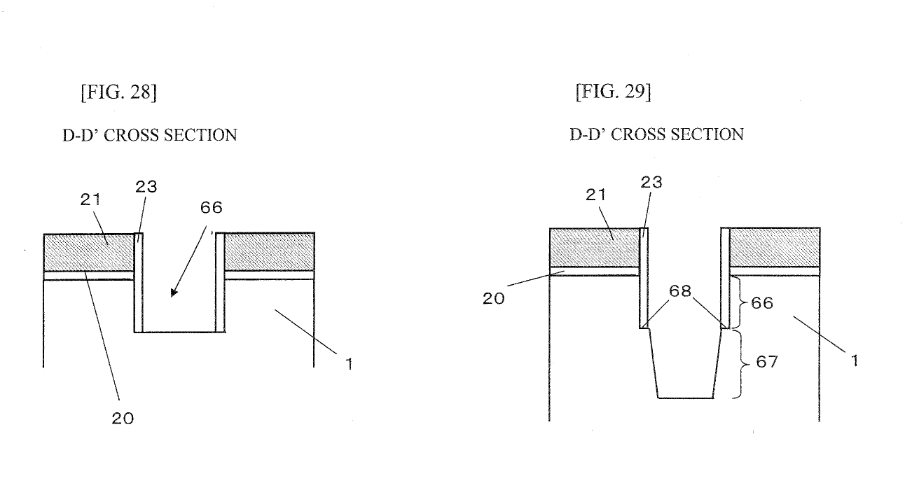

Then, as illustrated in FIG. 28, the silicon oxide film is formed over the entire surface of the resulting structure by the CVD method. The entire surface of the silicon oxide film is then dry-etched without using any mask layer to form a side wall (insulating film) 23 on an inner wall of the upper opening 66 (step (2)).

Then, as illustrated in FIG. 29, the silicon is dry-etched again through the first mask layer 21 and the side wall 23 as a mask to form a lower opening 67 under the upper opening 66 (step (3)). At this time, the angle of the side wall of the lower opening 67 to the vertical direction can be set according to desired transistor properties by changing etching conditions.

In this case, the step surface 68 is formed under the side wall (insulating film) 23. The sectional area of a cross section perpendicular to the depth direction can discontinuously change, between the upper opening 66 and the lower opening 67 across the step surface. The sectional area of the cross section of the upper opening 66 perpendicular to the depth direction is larger than that of the cross section of the lower opening 67 perpendicular to the depth direction.

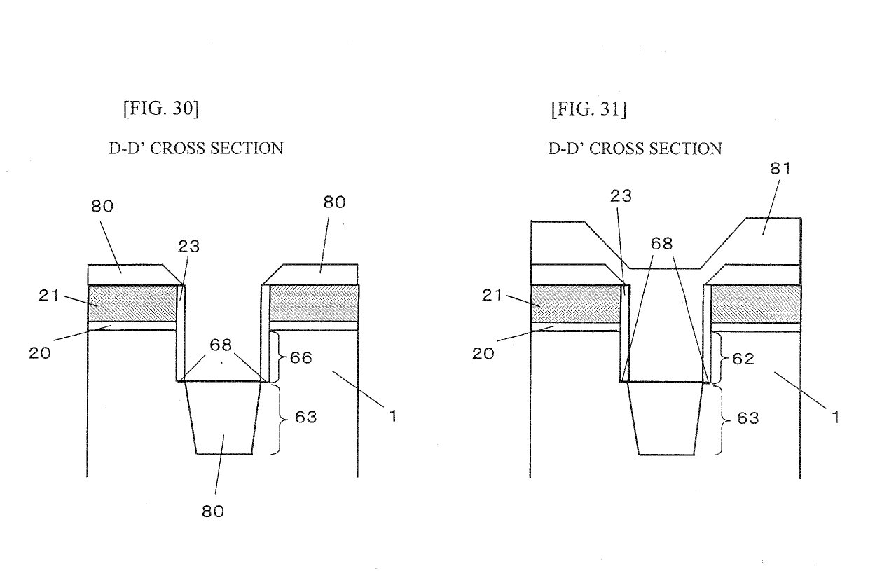

Then, as illustrated in FIG. 30, a silicon oxide film 80 is filled into the lower opening 67 by the CVD (Chemical Vapor Deposition) method or the HDP-CVD (High Density Plasma-Chemical Vapor Deposition) method. At the same time, the silicon oxide film 80 is also formed on a surface of the first mask layer 21 so that a side surface of the silicon oxide film 80 is inclined; this shape is inherent in the HDP. The isolation region 63 is formed in the lower opening (step (4)).

The CVD method allows the insulating material to be excellently filled into the fine opening. Thus, in step (4), if the insulating material is filled into the lower opening 67 by the CVD method, the insulating material can be uniformly filled into the lower opening 67 without generating any void.

Furthermore, step (4) allows the insulating material to be uniformly filled into the lower opening 67 by the HDP-CVD method. However, since the lower opening has a smaller sectional area than the upper opening, filling the lower opening with the insulating material is difficult. Thus, if in step (4), the insulating material is filled into the lower opening 67 by the HDP-CVD method, a void may be generated in the insulating material filled into the lower opening 67 depending on filling conditions. However, even in this case, no problem occurs if the void is formed at such a depth as prevents the void from being exposed when the isolation region is partly etched during an etching step or the like after the formation of the isolation region. Thus, as long as the film deposition is performed under such conditions as prevent a possible void from being exposed during the subsequent etching step, the HDP-CVD method can be used in step (4).

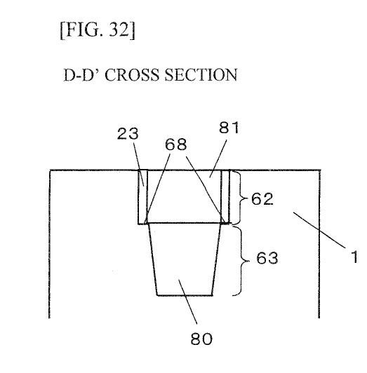

Then, as illustrated in FIG. 31, the insulating material is filled into the upper opening 66 by the HDP-CVD (High Density Plasma-Chemical Vapor Deposition) method. In this case, the HDP-CVD method allows the insulating material to be excellently filled in the depth direction compared to the CVD method, and thus enables a silicon oxide film 81 to be uniformly filled into the upper opening 66 at a high speed. Then, as illustrated in FIG. 32, flattening is performed by a CMP process to form the upper isolation region 62 (step (5)).

In step (1) of forming the upper opening and step (3) of forming the lower opening, the sectional areas of the upper and lower openings may or may not vary in the depth direction. The sectional areas of the upper and lower isolation regions formed in steps (4) and (5) are not particularly limited. However, the sectional area of a cross section of the upper isolation region perpendicular to the depth direction needs to be larger than that of a cross section of the lower isolation region perpendicular to the depth direction.

In steps (4) and (5), the insulating material filled into the upper and lower openings is not particularly limited provided that the material offers an insulating property. The insulating material may be the same or different. Furthermore, each of the upper and lower isolation regions need not entirely be composed of the same material but may be composed of a plurality of areas made up of different materials. In the present exemplary embodiment, steps (4) and (5) can be continuously carried out by forming both the lower and upper isolation regions made up of a silicon oxide film using the HDP-CVD method. Preferably, the upper isolation region is composed of silicon oxide, and the lower isolation region is composed of silicon nitride.

The isolation region may include a step surface which surrounds the entire periphery of a predetermined area or which is formed only in a part of the isolation region (the step surface may be formed so as not to surround the entire periphery of a predetermined area). The angle of the gradient of the side wall of each of the upper and lower isolation regions is not particularly limited. The gradient can be controlled to any angle by forming the upper and lower openings under predetermined conditions and by a predetermined method.

In the present exemplary embodiment, the side wall 23 is left as formed to form the lower and upper isolation regions. However, the side wall 23 may be removed after the formation of the lower opening and before the filling of the insulating material.

The isolation region according to the second exemplary embodiment is applicable even to between semiconductor elements with different widths in the depth direction, as an isolation region offering an excellent insulating property. As a result, the present exemplary embodiment allows various device designs to be effectively achieved.

### Third Exemplary Embodiment

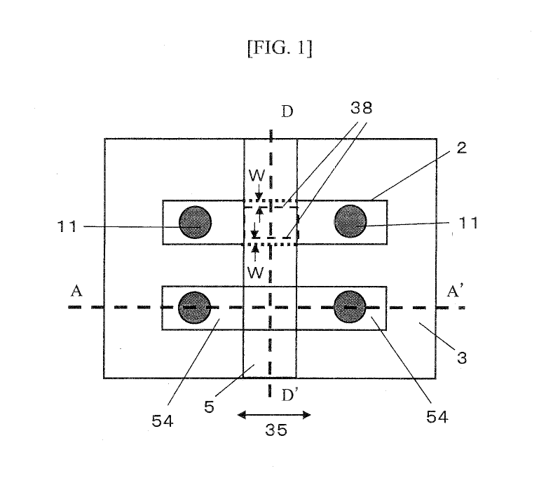

FIG. 1 is a plan view of a semiconductor device including two RC transistors formed on a semiconductor layer (not illustrated in the drawings) composed of silicon and an isolation region formed between the RC transistors;

the semiconductor device is formed by the manufacturing method according to the third exemplary embodiment. In FIG. 1, a diffusion layer area (active area) is illustrated at 2, and a gate trench is illustrated at 5. An isolation region 3 is formed around the diffusion layer area 2 so as to surround the diffusion layer area 2. A step surface is present in a part of the isolation region 3 which is in contact with the boundary between first semiconductor areas and a second semiconductor area (this is not illustrated in FIG. 1).

The diffusion layer area 2 extends in the direction of arrow 35 (longitudinal direction). As described below, the diffusion layer area 2 is formed of the first and second semiconductor areas. The position of a contact plug is illustrated at 11 in FIG. 1; the contact plugs 11 connect impurity diffusion layers for a source and a drain areas to wiring layers formed over the impurity diffusion layers, via a conductive area (first semiconductor area). In FIG. 1, the first semiconductor areas on the impurity diffusion layers for the source and the drain areas are omitted.

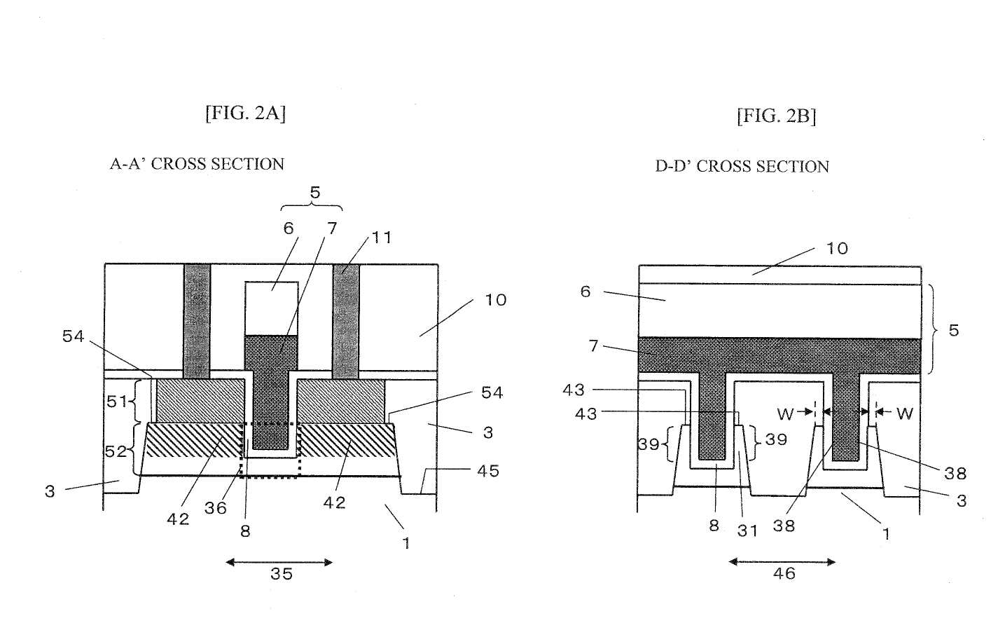

FIG. 2A shows a cross section taken along line A-A′ in FIG. 1. FIG. 2B shows a cross section taken along line D-D′ in FIG. 1. In FIG. 2A, the second semiconductor area is illustrated at 52, and a conductive area (first semiconductor area) is illustrated at 51. A semiconductor substrate composed of silicon is illustrated at 1; impurities are doped into the semiconductor substrate, which is thus of P type. The isolation region 3 is formed by STI (Shallow Trench Isolation) using a silicon oxide film (SiO₂) or the like and includes a step surface. The step surface is a top surface of the second semiconductor area 52 in which the conductive area 51 is not formed. The step surface is formed on the second semiconductor area 52 so as to surround the entire periphery of the conductive area 51. A stairway-like step structure is formed so as to form the step surface. A part of the isolation region 3 located above the step surface is an upper isolation region. A part of the isolation region 3 located below the step surface is a lower isolation region.

The gate trench 5 is formed of polycrystalline silicon (Poly-Si) 7 buried in the trench and a low-resistance conductive layer 6 such as tungsten (W) which is formed over the polycrystalline silicon (Poly-Si) 7. In the gate trench 5, the polycrystalline silicon (poly-Si) 7 forms a gate electrode and is buried in an intermediate portion of the first and second semiconductor areas 51 and 52 in an extending direction 35 in which the first and second semiconductor areas 51 and 52 extend. That is, the gate electrode 7 is buried in the intermediate portion of the second semiconductor area 52 in the extending direction 35 thereof and extends upward from the second semiconductor area 52. The conductive first semiconductor areas 51 are formed on the both sides, in the extending direction 35, of a part of the electrode 7 extending upward from the second semiconductor area 52.

In FIG. 2A, impurity diffusion layers for a source and a drain areas are illustrated at 42 and the impurity diffusion layers are formed by doping N-type impurities into the second semiconductor area 52. The impurity diffusion layers for the source and the drain areas are composed of the both portions of the second semiconductor area sandwiching a recess portion. The impurity diffusion layers 42 for the source and the drain areas form third semiconductor areas in the second semiconductor area 52. The gate insulating film 8 is formed between each of the first and second semiconductor areas 51 and 52 and the gate electrode 7.

An interlayer insulating film 10 made up of a silicon oxide film is formed so as to cover the gate trench 5. The conductive area 51 is formed on the impurity diffusion layers 42 for the source and the drain areas. The contact plug 11 is used to electrically connect a wiring layer (not illustrated in the drawings) formed above to the impurity diffusion layers 42 for the source and the drain areas. The conductive areas 51 are formed between the contact plugs 11 and the impurity diffusion layers 42 for the source and the drain areas 25 for electric connection. The impurity diffusion layers 42 for the source and the drain areas are formed in the second semiconductor area to make up the third semiconductor areas. A top surface of each of the impurity diffusion layers 42 has the same height.

As illustrated in FIGS. 2A and 2B, the intermediate portion of the second semiconductor area 52 in the direction of arrow 35 in which the gate electrode 7 is buried forms a recess portion 36. The recess portion 36 includes side portions 39 that are areas located both respective side surfaces A (reference numeral 38) of the gate electrode 7 parallel to the direction of arrow 35. The side portions 39 function as channel areas of the RC transistor. A P-type impurity implantation layer 31 is formed in each of the side portions 39 to adjust a threshold voltage. If the RC transistor is on, the side wall-like side portions 39 is changed from a P type to an N type according to an electric field applied by the gate electrode 7, resulting in the electric connection between the impurity diffusion layers 42 for the source and the drain areas.

The semiconductor device according to the third exemplary embodiment is characterized in that the side portions 39 of the recess portion include top surfaces 43 located level with a top surface 54 of each of the both ends, in the direction of arrow 35, of the second semiconductor area, formed in the diffusion layer area 2. The top surfaces 43 and 54 form the same step surface.

Since the top surfaces 43 of the side portions 39 are planar, the top surface 43 can have a width (the width in the direction of arrow 46 in FIG. 2B) W in a direction perpendicular to the extending direction 35 of the diffusion layer area. The predetermined width of the side portions 39 of the recess portion allows the height, shape, and width of parts of the side portions of the recess portion which functions as a channel area to be accurately controlled to desired values. As a result, the transistor can be prevented from varying with their properties.

That is, in the RC transistor according to the present exemplary embodiment, the channel area is thus formed away from the surface of the semiconductor layer. The parts of the second semiconductor area 52 are located at the respective ends of the channel area in the lateral direction 35 function as impurity diffusion layers for the source and the drain areas.

In the present exemplary embodiment, a thick insulating film may be formed at a bottom portion of the recess portion so that while the field effect transistor is on, only the side portions of the recess portion can function as channel areas. A thin insulating film may be formed at the bottom portion of the recess portion and allowed to function as a gate insulating film so that while the field effect transistor is on, the side portions and bottom portion (located immediately below the gate electrode) of the recess portion can function as channel areas. If the side and bottom portions of the recess portion function as channel areas, then in the second semiconductor area, the impurity diffusion layers for the source and the drain areas are preferably formed not only in the both portions sandwiching the side portions of the recess portion but also in the both portions sandwiching the bottom portion (located immediately below the gate electrode) of the recess portion.

As described above, in the semiconductor device according to the third exemplary embodiment, the diffusion layer area (active area) is composed of the first and second semiconductor areas. In the present exemplary embodiment, the “third semiconductor area” refers to the areas in the second semiconductor area in which the impurity diffusion layers 42 for the source and the drain areas are formed, that is, the areas in the second semiconductor area which are located on both sides sandwiching the recess portion in the predetermined direction. In the semiconductor device according to the third exemplary embodiment, the “conductive area”, that is, the “first semiconductor area” is the area formed over the third semiconductor area in contact with the third semiconductor area. If the third semiconductor areas are used as the impurity diffusion layers for the source and the drain areas, the first semiconductor area is conductive and electrically connects the impurity diffusion layers for the source and the drain areas to the contact plug.

In the present exemplary embodiment, the impurity diffusion layers for the source and the drain areas are formed in the second semiconductor area and thus defined as the “third semiconductor area”. In contrast, if the impurity diffusion layers for the source and the drain areas are formed in the first semiconductor areas, the “third semiconductor area” corresponds to any semiconductor areas positioned on the both sides in the second semiconductor area sandwiching the recess portion in a predetermined direction. The third semiconductor area may contain impurities of a concentration and a type different from those of the semiconductor areas other than the first and second semiconductor areas in the semiconductor device or impurities of the same concentration and type as those of the semiconductor areas other than the first and second semiconductor areas in the semiconductor device.

The first semiconductor area can be distinguished from the second semiconductor area as follows. That is, the area of a bottom surface of the first semiconductor areas is smaller than that of a top surface of the second semiconductor area. Thus, the step structure is formed at the boundary between the first and second semiconductor areas at the both ends in the extending direction of the diffusion layer area; the step structure includes an exposed top surface (corresponding to the step surface; for example, in FIG. 2A, the surface is located parallel to the semiconductor layer 45 and denoted by reference numeral 54) located parallel to the semiconductor layer formed under the second semiconductor area. In the semiconductor device according to the third exemplary embodiment, the first semiconductor area is defined as the portion located above the top surface (corresponding to the step surface) forming the step structure, and the second semiconductor area is defined as the portion located below the top surface.

Furthermore, in the semiconductor device according to the third exemplary embodiment, in the diffusion layer area, the concentration of impurities varies continuously between the impurity diffusion layers for the source and the drain areas and the conductive area located over the impurity diffusion layers. However, in the description below, the areas positioned in the second semiconductor area is defined as the impurity diffusion layers for the source and the drain areas, and the part positioned in the first semiconductor area is defined as the conductive area.

The “end of the second semiconductor area in the predetermined direction” corresponds to the end of the second semiconductor area in the direction in which the second semiconductor area extends. That is, in one example, the second semiconductor area is made up of the recess portion (central portion) and the ends (both sides) so that the first end, the recess portion, and the second end are arranged in this order in the extending direction of the second semiconductor area. In another example in which the second semiconductor areas of two transistors are partly shared by the transistors, the first end, the recess portion, the central portion, and the second end are arranged in this order in the extending direction of the second semiconductor area.

The “recess portion” is composed of the intermediate portion of the second semiconductor area in the extending direction of the second semiconductor area and constitutes the entire intermediate portion of the second semiconductor area in the thickness direction thereof. The recess portion is illustrated at 36 in, for example, FIG. 2A. A part of the gate electrode is buried in the recess portion.

The recess portion includes the side portions located opposite to the respective side surfaces A of the gate electrode which are parallel to the extending direction of the second semiconductor area. Each of the side portions includes the top surface (corresponding to the step surface) located level with the top surface (corresponding to the step surface) of the end of the second semiconductor area in the extending direction of the second semiconductor area. Thus, the recess portion has the areas with a predetermined width on the both sides located so as to sandwich the gate electrode in a direction perpendicular to the extending direction of the second semiconductor area.

The “gate electrode” corresponds to an electrode portion buried inside the intermediate portion of the first and second semiconductor areas in the extending direction of the second semiconductor area. In the third exemplary embodiment, the electrode portion buried in the semiconductor substrate (corresponding to the first and second semiconductor areas) is defined as the gate electrode. Portions formed on the semiconductor substrate and including the low-resistance conductive layer are not included in the gate electrode. Portions formed on the semiconductor substrate and including the gate electrode and the low-resistance conductive layer form gate trenches.

The “third semiconductor area” corresponds to any semiconductor areas positioned on the both sides in the second semiconductor area sandwiching the recess portion in the predetermined direction as described above. If the impurity diffusion layers for the source and the drain areas are formed in the second semiconductor area, the impurity diffusion layers form the “third semiconductor area”.

A method of manufacturing the semiconductor device according to the present exemplary embodiment will be described below in detail.

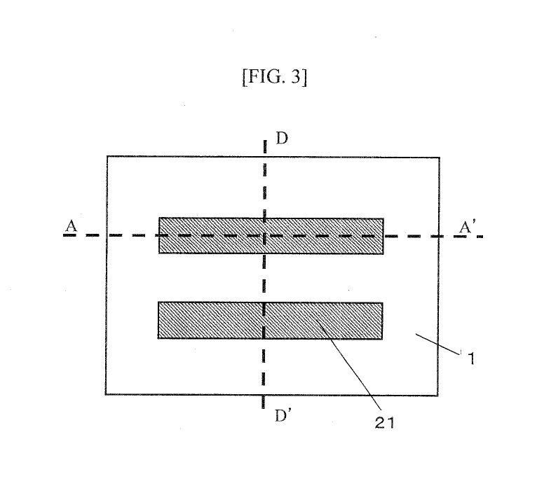

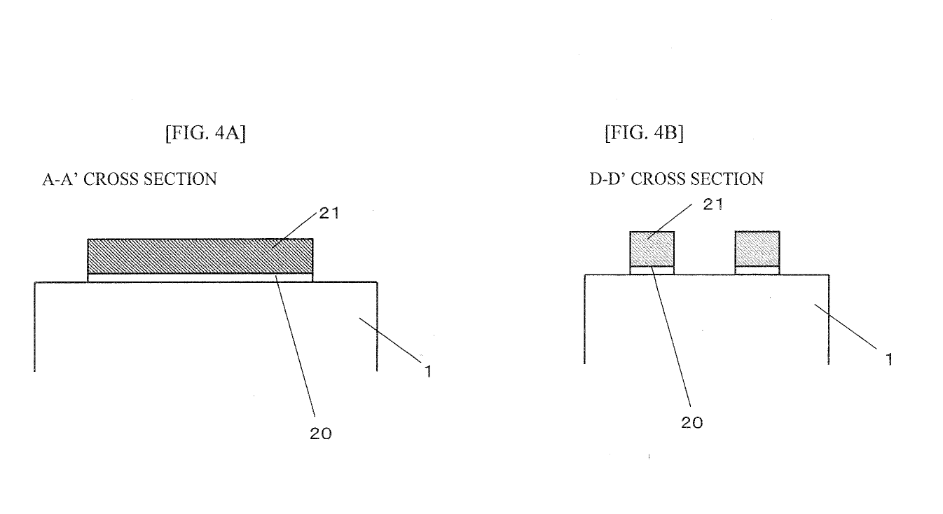

First, as illustrated in a plan view in FIG. 3, the first mask layer (reference numeral 21) is formed on the semiconductor substrate 1 composed of P-type silicon; the diffusion layer area 2 (FIG. 1) is to be formed using the first mask layer. FIG. 4A shows a cross section taken along line A-A′ in FIG. 3. FIG. 4B shows a cross section taken along line D-D′ in FIG. 3.

As specifically illustrated in FIGS. 4A and 4B, a silicon oxide film (first insulating layer) 20 of thickness about 9 nm is formed on the semiconductor substrate 1 by a thermal oxidation method or the like. A silicon nitride film (Si₃N₄: first mask layer) 21 of thickness about 120 nm is formed on the silicon oxide film 20. The silicon oxide and nitride films 20 and 21 are patterned using the dry etching method so as to leave a portion forming the diffusion layer area 2. The patterning allows a desired shape to be formed using a photo resist film (not illustrated in the drawings).

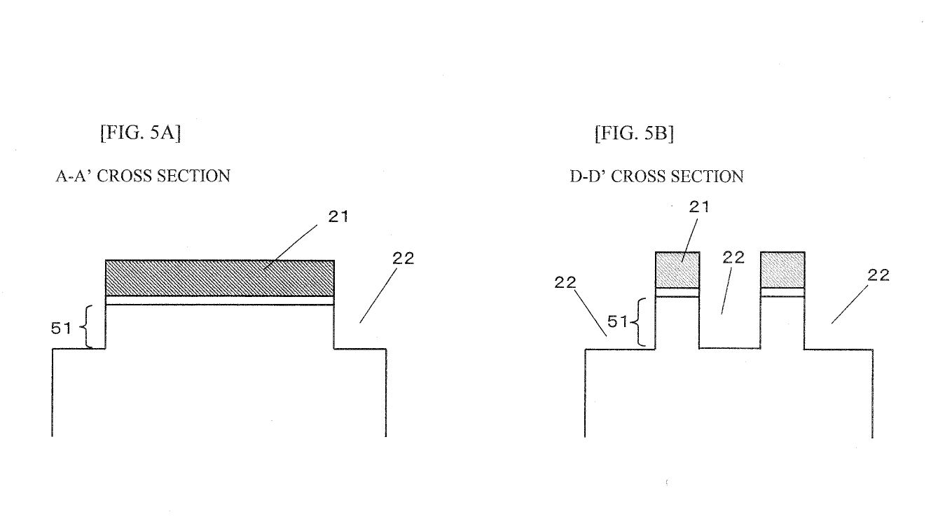

In FIGS. 5 to 9, 11 to 14, and 16 to 19 referenced in the description below, the cross section taken along line A-A′ in FIGS. 1 and 3 is illustrated in drawings with a figure number with A at the trailing end. The cross section taken along line D-D′ in FIGS. 1 and 3 is illustrated in drawings with a figure number with B at the trailing end.

Then, as illustrated in FIGS. 5A and 5B, the silicon is dry-etched to form the upper opening 22 of depth about 120 nm in an area of the semiconductor substrate 1 which is not covered with the first mask layer 21. At this time, the projecting first semiconductor areas 51 are formed under the silicon oxide film. Specific manufacturing conditions for the dry etching include, for example, the use of gas containing a mixture of chloride (Cl₂), hydrogen bromide (HBr), oxygen (O₂), and the like, and an atmosphere with a pressure of 10 to 50 mTorr.

In this case, the angle (taper angle) of the side wall of the upper opening 22 to the vertical direction can be adjusted by varying the flow rate of the etching gas or the like. In this case, the side wall extends substantially perpendicularly to the vertical direction (taper angle: 0°)

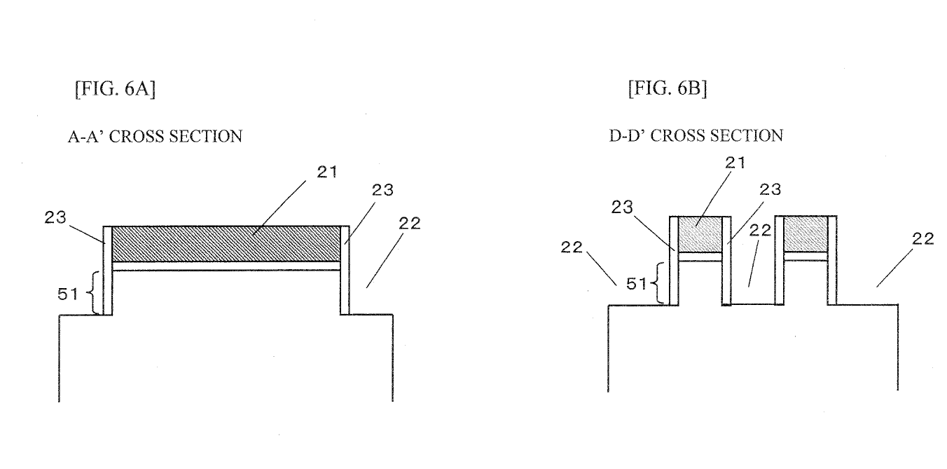

Then, as illustrated in FIGS. 6A and 6B, the silicon oxide film of thickness about 30 nm is formed by the CVD method. The entire surface of the silicon oxide film is then dry-etched without using any mask layer to form the side wall 23 on the side portion of the upper opening 22 (step (2)).

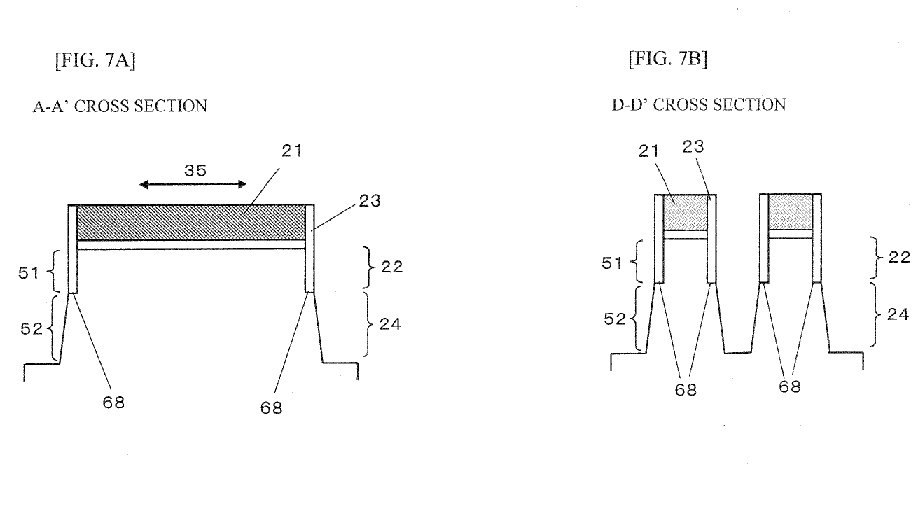

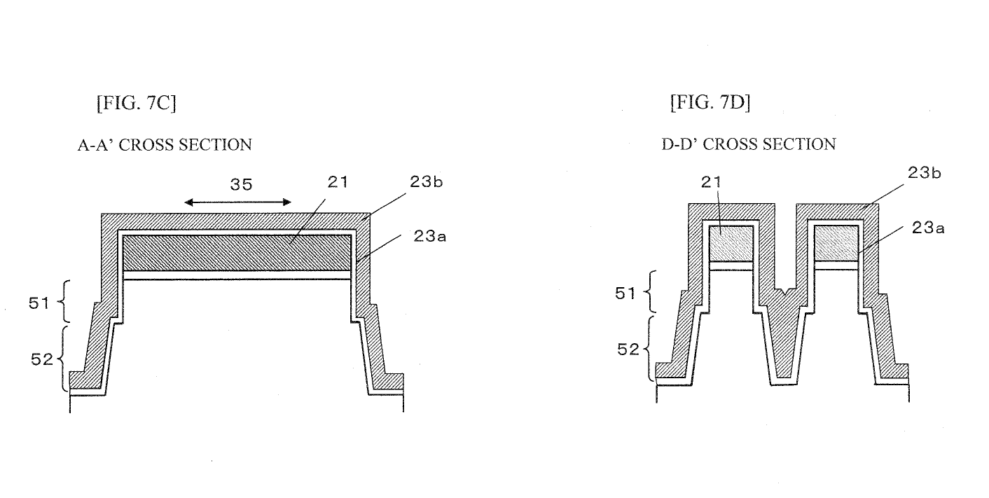

Then, as illustrated in FIGS. 7A and 7B, the silicon is dry-etched again using the first mask layer 21 and the side wall 23 as a mask to form a lower opening 24 of depth about 120 nm (step (3)). At this time, the second semiconductor area 52 extending in the direction of arrow 35 is formed under the semiconductor area 51. At the same time, the step surface 68 is formed under the side wall 23. The angle of the side wall of the lower opening 24 to the vertical direction can be set according to desired transistor properties by changing etching conditions.

Then, as illustrated in FIGS. 7C and 7D, the side wall 23 is removed. A silicon oxide film 23a of thickness 6 nm is then formed by the thermal oxidation method. Moreover, a silicon nitride film 23b of thickness 30 nm is formed by the CVD method so as to fill the lower opening 24 between the adjacent second semiconductor areas 52. The silicon nitride film 23b is formed by means of a well-known low-pressure CVD method using dichlorosilane and ammonia as a material gas.

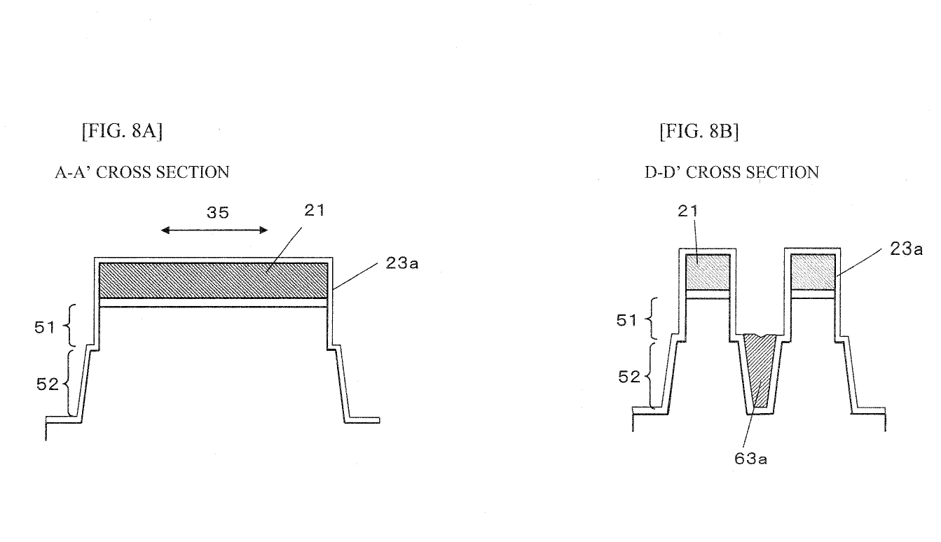

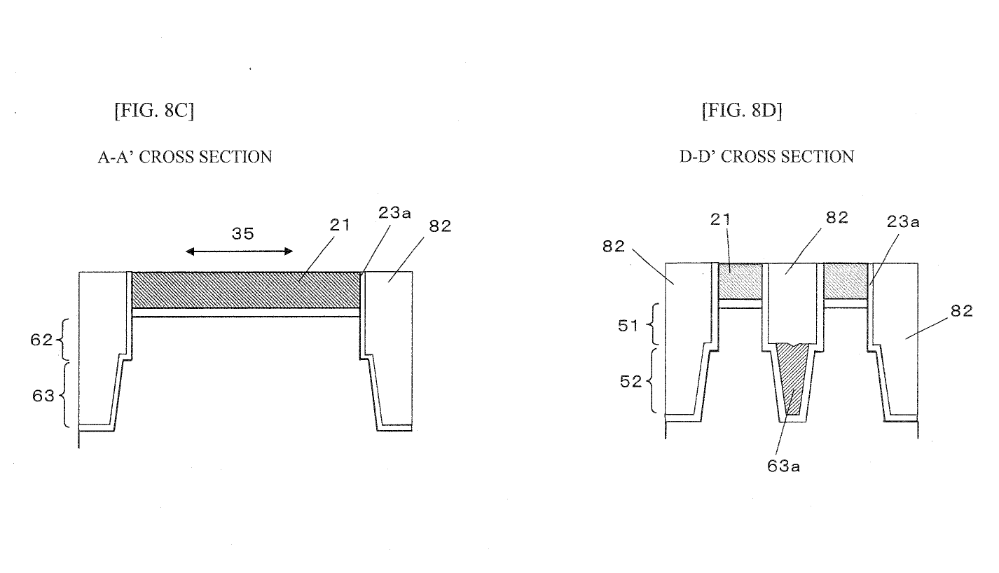

Then, as illustrated in FIGS. 8A and 8B, the silicon nitride film 23b is wet-etched using hot phosphoric acid. The silicon nitride film 23b is filled only into the lower opening 24 (step (4)). The silicon nitride film 23b formed in the lower opening 24 between the adjacent diffusion layer areas (first semiconductor area 51 and second semiconductor area 52) is three to four times as thick as the films deposited in the other parts. Thus, the above-described wet etching allows the silicon nitride film 63a to remain only inside the lower opening 24 between the adjacent diffusion layer areas 2 in a self-aligned manner. In this case, in the wide area of the lower opening 24 between the diffusion layer areas located away from each other, the silicon nitride film 23b is etched away.

Then, as illustrated in FIGS. 8C and 8D, a silicon oxide film 82 is formed using the HDP-CDV method, so as to be thicker than the surface of the first mask layer 21. The silicon oxide film 82 is further flattened by the CMP method using the first mask layer 21 as a stopper (step (5)). At this time, in the wide area between the diffusion layer areas located away from each other, the silicon oxide film 82 is filled into the upper and lower openings 22 and 24.

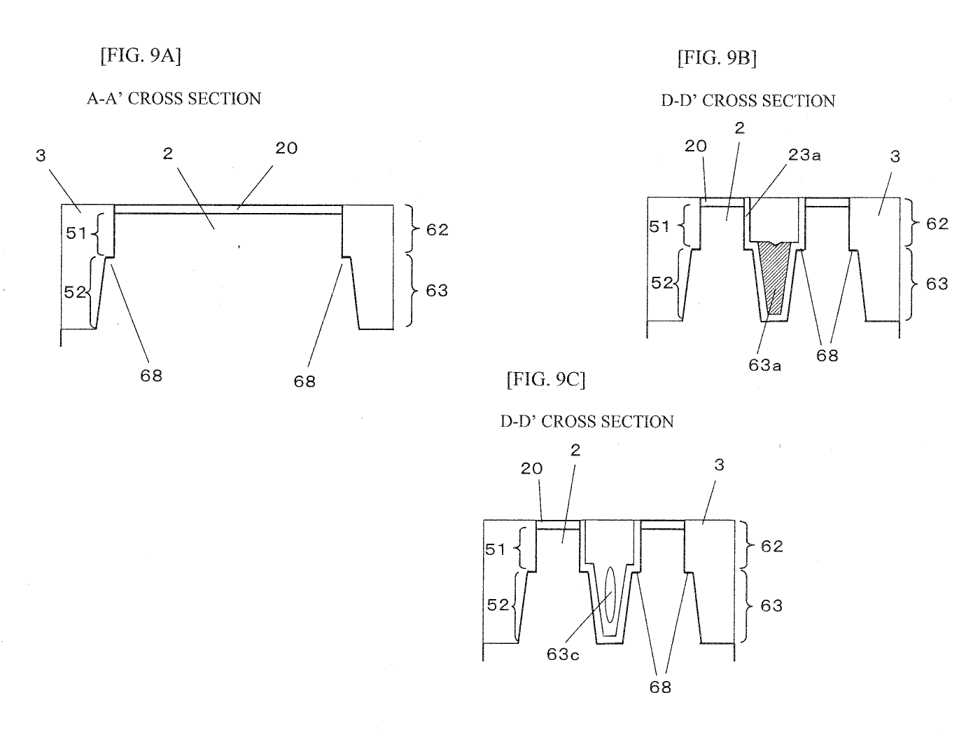

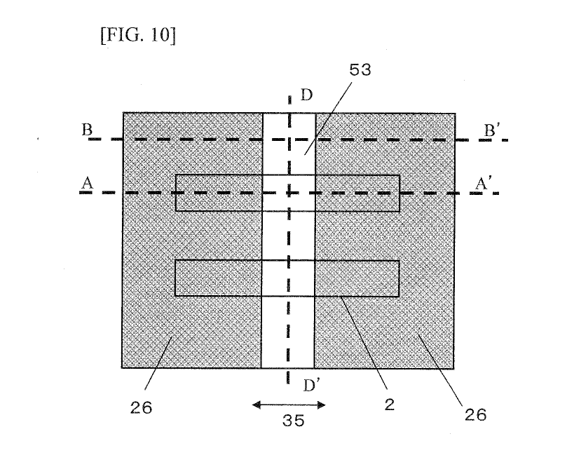

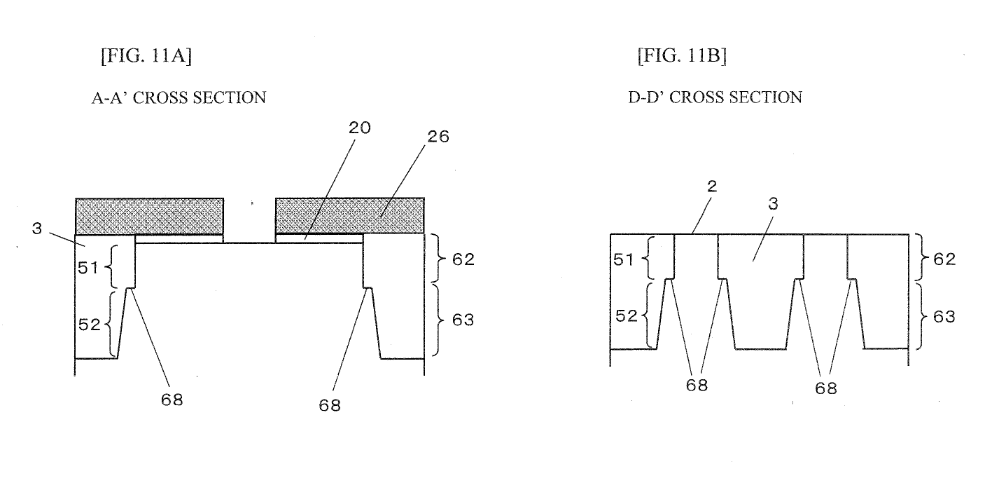

Then, as illustrated in FIGS. 9A and 9B, the silicon oxide film 82 is etched back to the surface of the semiconductor substrate. The first mask layer 21, made up of the silicon nitride film, is further etched away by hot phosphoric acid. An isolation region is thus formed.

In the wide area between the diffusion layer areas located away from each other, the isolation region including the upper and lower isolation regions 62 and 63 is formed such that both the upper and lower openings 22 and 24 are filled with the silicon oxide film 82. On the other hand, in the narrow part of the isolation region between the adjacent diffusion layer areas 2, the lower isolation region 63 is formed of a laminate structure of the nitride silicon film and the silicon oxide film. The upper isolation region 62 is formed only of the silicon oxide film. This isolation structure avoids generating a void in the isolation region and using a material such as SOG which involves fixed charges. Thus, the isolation region can be prevented from affecting a transistor to be formed in the subsequent steps.

As illustrated in FIG. 9C, as is the case with the second exemplary embodiment, if the lower isolation region is also formed of a silicon oxide film using the HDP-CVD method, instead of the silicon nitride film, a void 63c is generated in the narrow portion. However, the void 63c is prevented from being exposed from the surface of the isolation region during the subsequent etching step. Thus, with the method of manufacturing the semiconductor device according to the third exemplary embodiment, the HDP-CVD method can be used to form the lower isolation region.

The silicon oxide film 23a previously formed is composed of the same material as that of the silicon oxide film 82 formed by the HDP-CVD method. Thus, in figures described below, the boundary between the silicon oxide films 23a and 82 is not illustrated for simplification.

As described above, the insulating material remains only inside the opening formed in the semiconductor substrate 1 to form the isolation region 3. The area of the semiconductor substrate 1 partitioned by the isolation region 3 corresponds to the diffusion layer area (active area; the first and second semiconductor areas 51 and 52) 2.

The height of the surface of the semiconductor substrate 1 may be set equal to that of the isolation region 3 by removing the first mask layer 21 and then removing the silicon oxide film located in the vicinity of the surface of the isolation region 3 by wet etching using a chemical such as fluorinated acid. If such processing is carried out, then the silicon oxide film 20 previously formed is also removed. Thus, the silicon oxide film 20 of thickness about 9 nm may be formed again, by thermal oxidation or the like, in an area from which silicon is exposed.

A process of manufacturing the RC transistor will be described below with reference to FIG. 10 and the subsequent figures. In FIGS. 10 to 19 described below, the silicon oxide film 23a is omitted. The boundary between the upper and lower isolation regions 62 and 63 is also omitted.

First, as illustrated in a plan view in FIG. 10, a silicon nitride film (second mask layer) 26 including an opening 53 in the entire intermediate portion of the first semiconductor areas in the direction of arrow 35 is formed to a thickness of about 120 nm. The silicon nitride film 26 is then patterned by dry etching so as to open the area of the gate electrode 7 (FIG. 1) (step (6)).

FIGS. 11A and 11B show the sectional shape of the silicon nitride film 26 after patterning. For the dry etching of the silicon nitride film 26, a specific available etching gas is, for example, a mixture of CF₄ (carbon tetrafluoride), CHF₂, and argon (Ar). In this case, the silicon oxide film 20 previously formed is very thin and is 9 nm in thickness. The silicon oxide film 20 is thus removed during etching of the silicon nitride film 26 to expose the silicon surface of the semiconductor substrate 1. On the other hand, since the silicon oxide film in the isolation region 3 is sufficiently thick, the silicon oxide film on the surface is only slightly scraped. Consequently, the functions of the silicon oxide film as an insulating film for the isolation region are not affected.

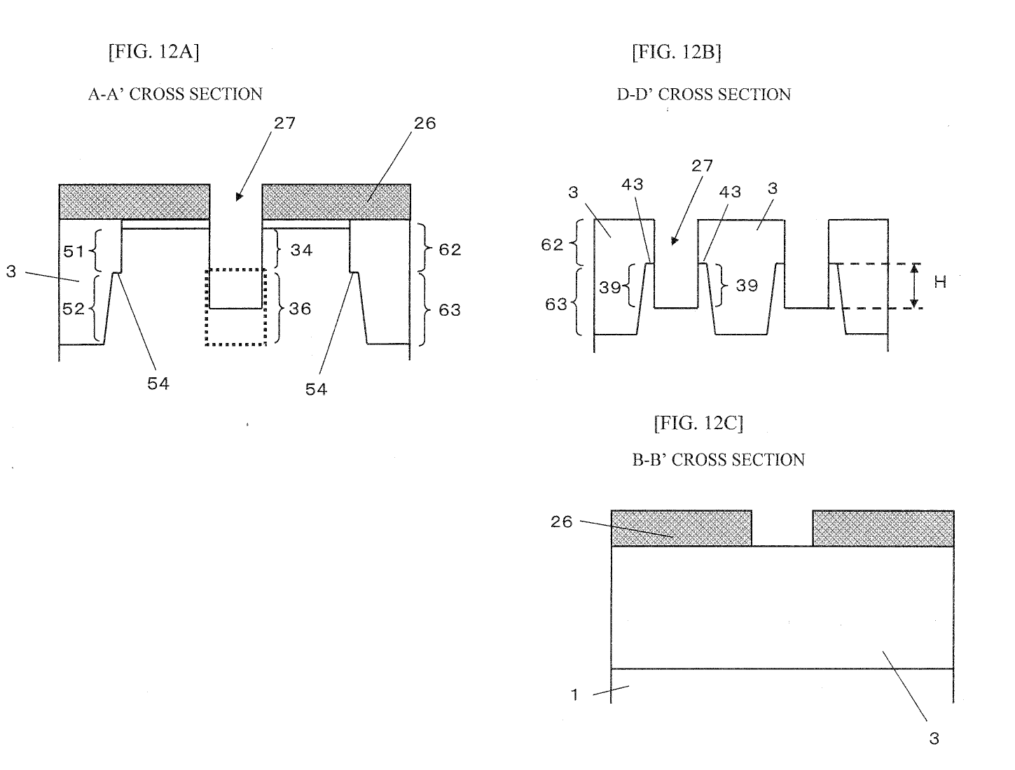

Then, as illustrated in FIGS. 12A and 12B, the silicon is anisotropically etched under set conditions for a high selectivity for the silicon nitride film 26 and the silicon oxide film forming the isolation region 3. A side surface (silicon surface) of a trench portion is formed by etching so as to have a perpendicular shape. In this case, a specific available etching gas is, for example, a mixture of chloride (Cl₂), hydrogen bromide (HBr), and oxygen (O₂). This etching removes the silicon from the exposed portion of the silicon surface to form trench portions 27 such that openings A (34 in FIG. 12A) are formed in the intermediate portion in the first semiconductor areas in the predetermined direction and such that a recess portion 36 is formed in the intermediate portion in the second semiconductor area in the predetermined direction.

In this case, in the D-D′ cross section, as illustrated in FIG. 12B, the silicon oxide film in the isolation region 3 and the upper isolation region serves as a mask to form side portions 39 of the recess portion each of which has a top surface (corresponding to a step surface) 43 located level with a top surface (corresponding to a step surface) 54 of a corresponding one of the both ends of the second semiconductor area 52, in the intermediate portion in the diffusion layer area (step (7)). Furthermore, in this case, the height (illustrated by H in FIG. 12B) of each of the side portions 39 of the recess portion is set to 30 to 60 nm.

Each of the side portions 39 of the recess portion functions as a channel area of the RC transistor. The width (corresponding to a portion illustrated by W in FIG. 2B) of the top surfaces of the side portions 39 of the recess portion are determined by the film thickness of the side wall 23 (FIG. 7B). Thus, the film thickness of the side wall 23 may be adjusted according to desired transistor properties during the formation of the side wall 23. With the operational properties of the RC transistor taken into account, the side wall is preferably formed such that W=about 10 to 50 nm. The height H of the side portion 39 of the recess portion may also be determined according to the desired transistor properties.

FIG. 12C shows a cross section of the structure after the etching, taken along line B-B′ in FIG. 10. In the B-B′ cross section, the pattern of the silicon nitride film 26 is formed on the isolation region 3, the trench 27 is not formed (the boundary between the silicon oxide film 20 and the isolation region 3 is not illustrated in the figure).

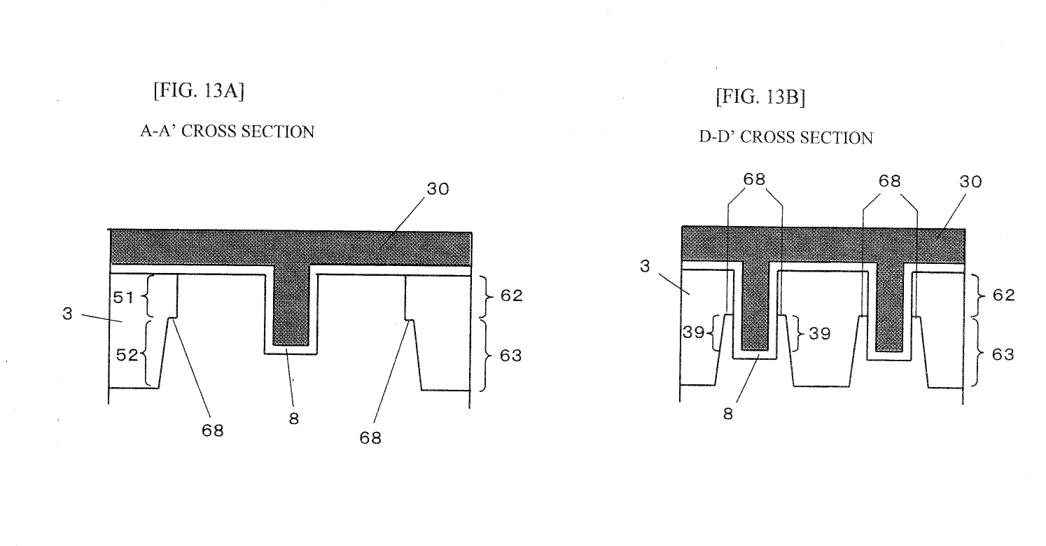

Then, the silicon nitride film (second mask layer) 26, used as a mask, and the silicon oxide film (first insulating layer) 20 are removed (step (8)) to expose the silicon surface from the diffusion layer area 2. Subsequently, as illustrated in FIGS. 13A and 13B, the gate insulating film 8 of thickness 4 to 8 nm is formed on inner walls of the openings A and the recess portion (step (9)).

Examples of the gate insulating film include a silicon oxide film, a laminate film of a silicon nitride film and a silicon oxide film, and a high-K film (for example, an HfSiON film) with a high dielectric constant.

Subsequently, the polycrystalline silicon film 30 of thickness about 100 nm into which phosphorus is doped as impurities is formed using the CVD method, so as to fill the trench portion 27. At this time, a gate electrode is formed (step (10)). Alternatively, instead of the conductive polycrystalline silicon film, a silicide film may be formed. The silicide film may be formed by, for example, sequentially forming a polysilicon film and a metal film and performing thermal treatment to cause silicidizing reaction. The type of the metal is not particularly limited provided that the metal can be silicidized through reaction with silicon. The metal may be, for example, Ni, Cr, Ir, Rh, Ti, Zr, Hf, V, Ta, Nb, Mo, or W. The silicide may be, for example, NiSi, Ni₂Si, Ni₃Si, NiSi₂, WSi₂, TiSi₂, VSi₂, CrSi₂, ZrSi₂, NbSi₂, MoSi₂, TaSi₂, CoSi, CoSi₂, PtSi, Pt₂Si, or Pd₂Si.

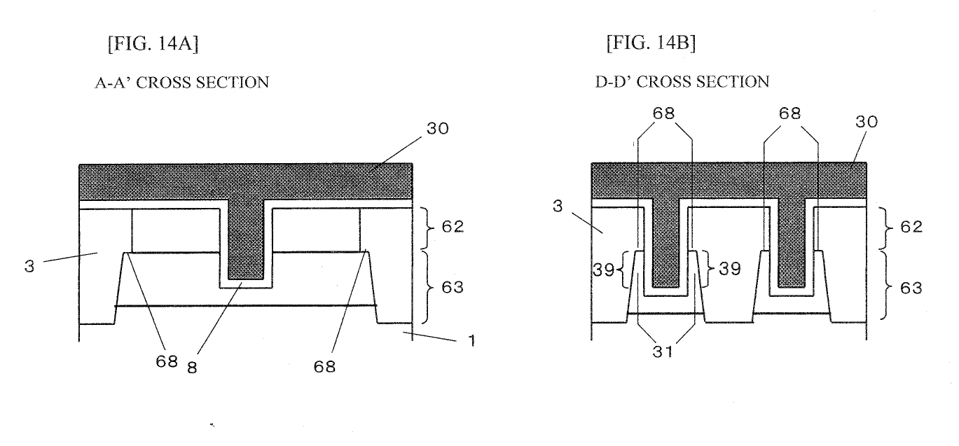

Then, as illustrated in FIGS. 14A and 14B, boron (B) ions are implanted at an energy of 50 to 80 KeV so as to penetrate the polycrystalline silicon film 30 and reach the area in which the side portions 39 of the recess portion, functioning as a channel area, is formed. The impurity implantation layer 31 is thus formed (step (11C)). The threshold voltage of the transistor can be adjusted to a desired value by regulating the concentration of boron implanted into the impurity implantation layer 31 (the dose of ion implantation). In actuality, since the concentration of the impurity implantation layer 31 varies continuously, the boundary between the impurity implantation layer 31 and the semiconductor substrate 1 is not clear. However, for description, a clear boundary is illustrated in FIGS. 14A and 14B. The illustration of the boron implanted into the isolation region 3 is omitted because this is irrelevant to the operation of the transistor.

Subsequently, a low-resistance conductive layer is formed on the polycrystalline silicon film 30. Specifically, the low-resistance conductive layer may be a high melting-point metal film such as tungsten (W), cobalt (Co), or titanium (Ti) or a silicide compound (WSi, CoSi, or TiSi) containing the high melting-point metal. Alternatively, the high melting-point metal film may be laminated on the polycrystalline silicon film 30 using a nitride (WN, TiN, or the like) of the high melting-point metal as a barrier film. Alternatively, if the silicide film is used instead of the polycrystalline silicon film 30 as described above, the lamination of the high melting-point metal film may be omitted.

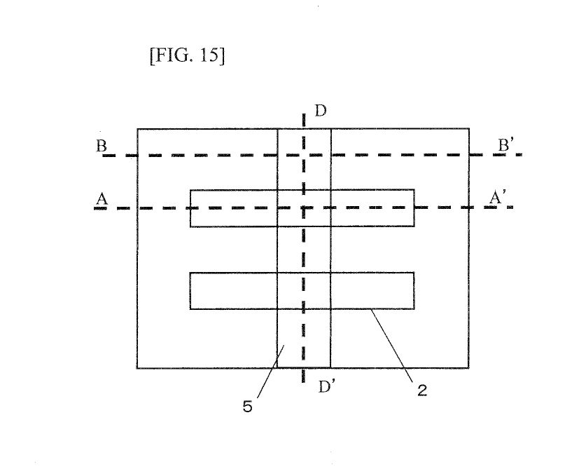

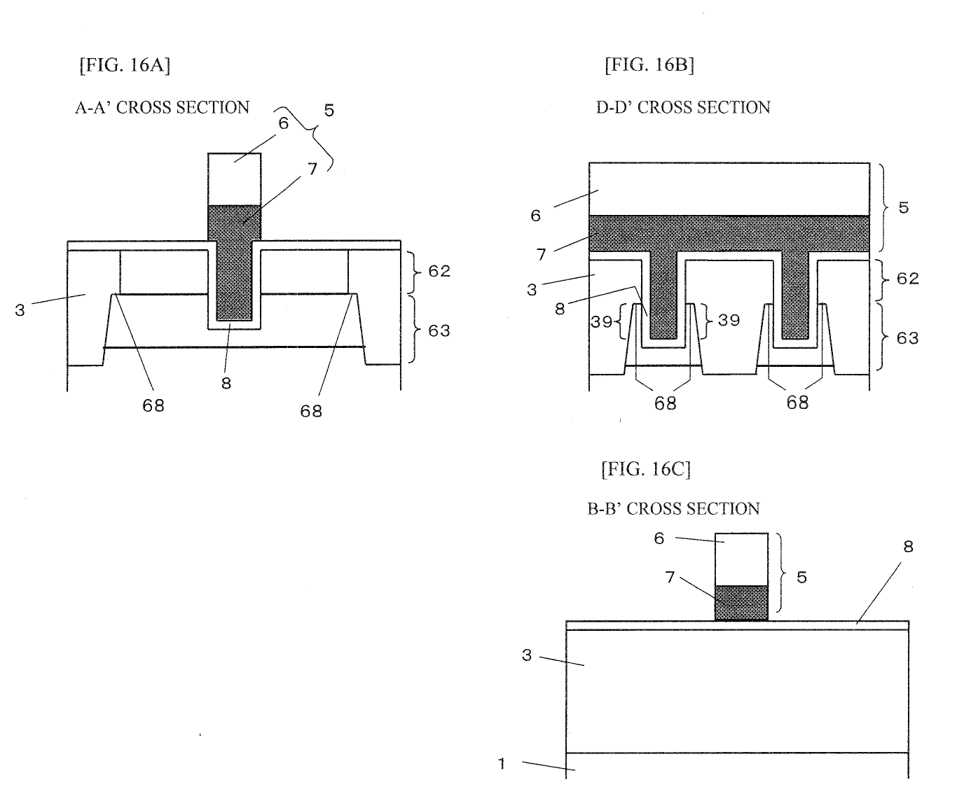

Subsequently, as illustrated in a plan view in FIG. 15, dry etching is performed using the photo resist film (not illustrated in the drawings) as a mask SO as to leave only the area of the gate trench 5. FIGS. 16A and 16B show a cross section of the gate trench after patterning. FIG. 16C shows a cross section taken along line B-B′ in FIG. 15. A lower part of the gate trench 5 (that is, the gate electrode) formed by patterning the polycrystalline silicon film 30 previously formed is illustrated at 7. An upper part of the gate trench 5 formed by patterning the low-resistance conductive layer is illustrated at 6.

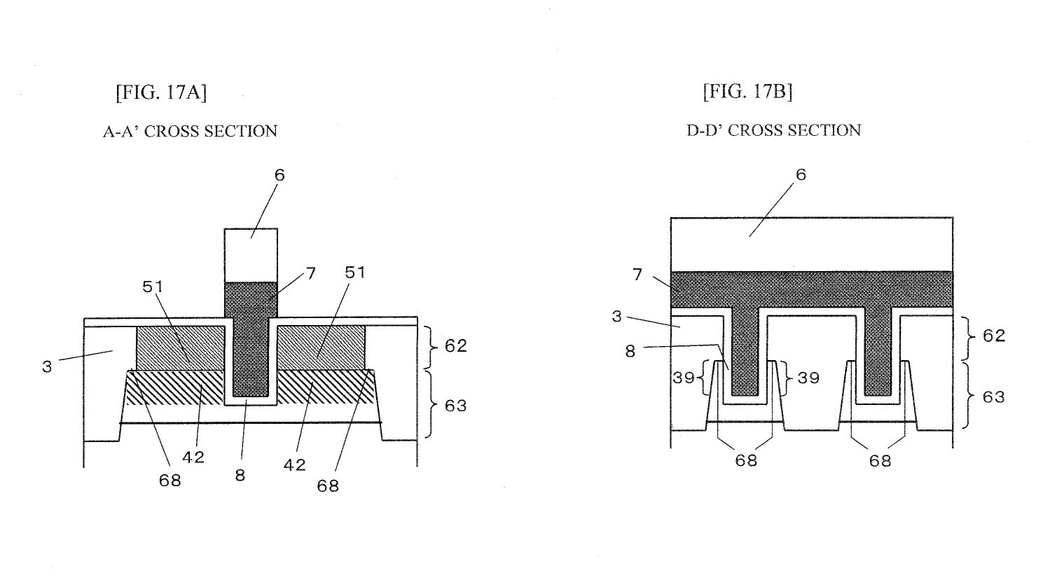

Then, as illustrated in FIGS. 17A and 17B, phosphorous (P) ions are implanted into the first and second semiconductor areas 51 and 52 in the diffusion layer area 2 at an energy of 10 to 20 KeV and a dose of 1×10¹² to 1×10¹³ ions/cm2 to form N-type impurity diffusion layers (step (11D)). Here, the N-type impurity diffusion layers formed in the second semiconductor area 52 functions as a source and a drain areas 42 (the N-type impurity diffusion layers correspond to the third semiconductor areas). The N-type impurity layers formed in the first semiconductor areas 51 functions as a conductive area.

Then, the interlayer insulating film 10 (FIG. 2A) is formed using a silicon oxide film or the like, so as to cover the gate trench 5. The contact plug 11 (FIG. 2A) is formed so as to connect to a conductive area 9 formed on the impurity diffusion layers 42 for the source and the drain areas. Also for the gate trench 5, a lead-out contact plug (not illustrated in the drawings) may be formed.

Subsequently, a metal wiring layer connected to the contact plug 11 is formed using tungsten, aluminum (Al), copper (Cu), or the like, to complete the RC transistor according to the third exemplary embodiment.

In the RC transistor, the width of the recess portion in a direction parallel to the direction in which the diffusion layer area extends may be determined according to the desired transistor properties. In particular, when the RC transistor is applied to the formation of a fine transistor including a recess portion of width (the width in the direction of arrow 35 in FIG. 2A) of 100 nm or less, a high-performance transistor with a decrease in threshold voltage inhibited can be easily formed.

In the above-described RC transistor, parts (third semiconductor area) of the recess portion 36 of the channel area in the second semiconductor area 52 which are positioned at laterally both ends thereof function as the impurity diffusion areas for the source and the drain areas. This aspect may be varied as follows.

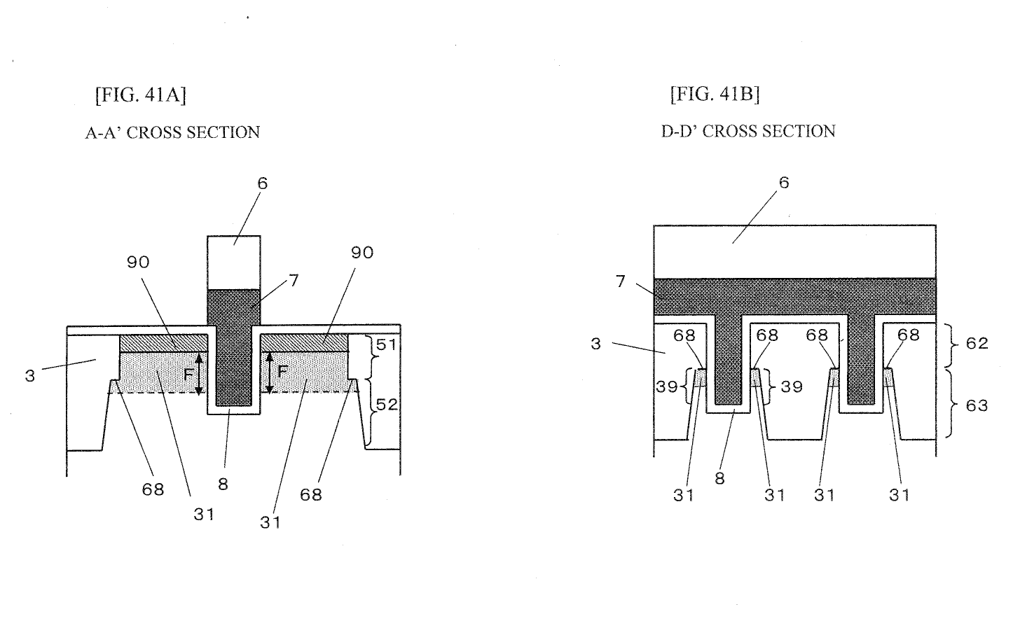

This variation will be described with reference to FIGS. 41A and 41B. The A-A′ cross section in FIG. 1 corresponds to FIG. 41A. The D-D′ cross section in FIG. 1 corresponds to FIG. 41B. In the steps illustrated in FIGS. 17A and 17B, the energy of the phosphorous ion implantation is adjusted to form N-type impurity diffusion layers 90 in the upper areas of the first semiconductor areas 51 as illustrated in FIG. 41A (step (11B)). Furthermore, by adjusting the energy of the boron ion implantation performed to adjust the threshold voltage of the transistor as described above with reference to FIGS. 14A and 14B, the impurity implantation layers 31 are formed to lie in the lower parts of the first semiconductor areas 51 and in the upper part of the second semiconductor area 52 as illustrated in FIG. 41A (step (11A)). In this example, the impurity implantation layers 31 are formed to lie in the lower parts of the first semiconductor areas 51 and in the upper part of the second semiconductor area 52. In step (11A), as described below, impurities may be implanted into the first semiconductor areas 51 to form the impurity implantation layers 31 only in the first semiconductor areas 51 or impurities may be implanted into the second semiconductor area 52 to form the impurity implantation layers 31 only in the second semiconductor area 52.

In this variation, the N-type impurity diffusion layers 90 function as the impurity diffusion layers for the source and the drain areas of the RC transistor. Furthermore, the threshold voltage of the transistor can be adjusted by the concentration of impurities in an area shown by arrow F instead of the concentration of impurities in the recess portion 36 of the channel area. That is, in this variation, the threshold voltage of the whole RC transistor can be determined by a threshold voltage at which the conductivity type of a part opposite the gate electrode is inverted in the semiconductor area with the impurity implantation layer 31 formed therein. Thus, the threshold voltage of the RC transistor can be easily adjusted without affecting the electrical characteristics (a depletion condition and the like) of the recess portion of the channel area by the ion implantation for adjusting the threshold voltage. Moreover, in the structure of the transistor illustrated in the variation, the recess portion 36 of the channel area is prevented from directly contacting the N-type impurity diffusion layers 90. Thus, even if a transistor with a short gate length is manufactured by miniaturization, a possible short channel effect can be prevented to enable the threshold voltage to be easily controlled.

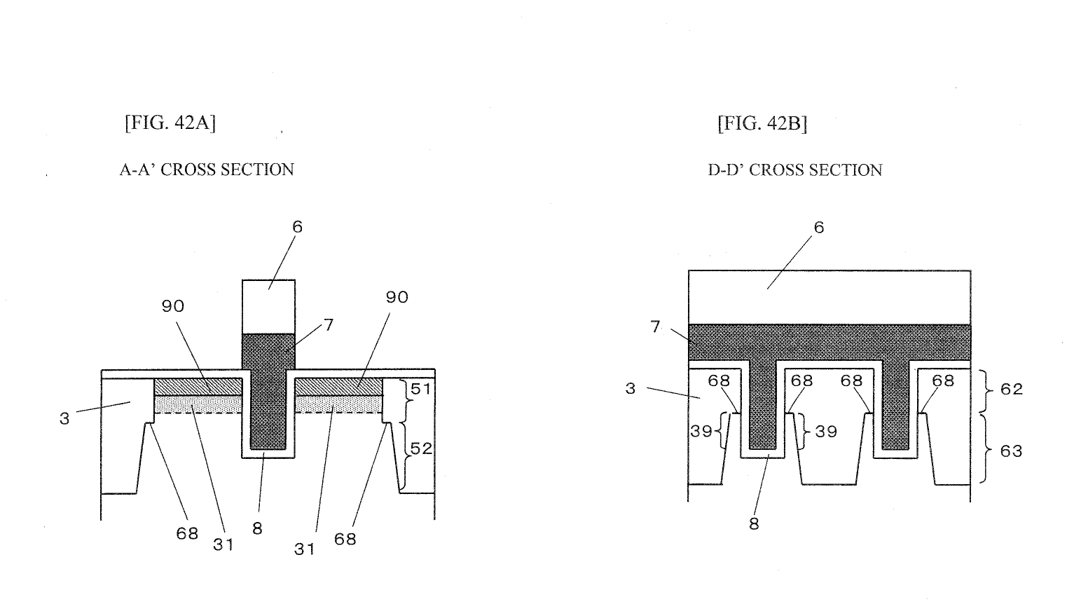

As illustrated in FIGS. 42A and 42B, the impurity implantation layers 31 may be entirely located inside the first semiconductor areas 51. The threshold voltage of the transistor can be controlled by the value of the threshold voltage of the area of current path (channel) which has the highest threshold voltage in the areas of the current paths formed between the impurity diffusion layers for the source and the drain areas. Therefore, in this case, the threshold voltage of the transistor can be controlled by the concentration of the impurity implantation layer 31.

In the above-described exemplary embodiments, the N-channel transistor is formed. However, a P-channel transistor can be similarly formed by changing the conductivity type of the impurities. That is, if a P-type semiconductor substrate is used, an N-type well is preformed and an RC transistor is formed in the well. To form impurity diffusion layers for a source and a drain areas, a P-type impurity layer may be formed by implantation of boron or boron fluoride (BF₂). Even for the P-channel transistor, the threshold voltage can be adjusted by controlling the concentration and conductivity type of the impurity layer implanted into the channel area. The present exemplary embodiment avoids using a material such as SOG which involves fixed charges, for the isolation region located adjacent to the side portions 39. Consequently, a disadvantageous possible variation in the threshold voltage of the transistor can be avoided to provide a reliable semiconductor device.

Furthermore, to enhance the properties of the transistor, an LDD structure may be used instead of the above-described single drain structure. Specifically, a side wall of a silicon nitride film or the like may be formed, by well-known means, on side portions of the low-resistance conductive layer 6 and a part of the polycrystalline silicon 7 which is positioned above the semiconductor substrate surface. Subsequently, for the N-channel transistor, impurities such as arsenic (As) may be doped at a dose of 1×10¹³ to 1×10¹⁴ ions/cm² using the ion implantation method. The LDD structure reduces the resistance value of the impurity diffusion layers for the source and the drain areas or the conductive area formed over the impurity diffusion layers. A large on current can thus be obtained.

Moreover, techniques for improving transistor performance which are used for related planar MOS transistors or simple trench gate transistors may be combined together without departing from the spirit of the third exemplary embodiment.

### Fourth Exemplary Embodiment

Another exemplary embodiment of the fourth exemplary embodiment will be described below.

The semiconductor device is formed as is the case with the third exemplary embodiment from the beginning of the process until the side portions 39 of the recess portion for the channel area are formed as illustrated in FIGS. 12A and 12B, referenced for the description of the third exemplary embodiment. However, in this case, in step (7), the trench 27 for the gate trench is formed to be deeper than that in the third exemplary embodiment. That is, in the third exemplary embodiment, the height (illustrated by H in FIG. 12B) of each of the side portions 39 of the recess portion is 30 to 60 nm. However, in the present exemplary embodiment, the height of each of the side portions 39 of the recess portion is 90 to 110 nm.

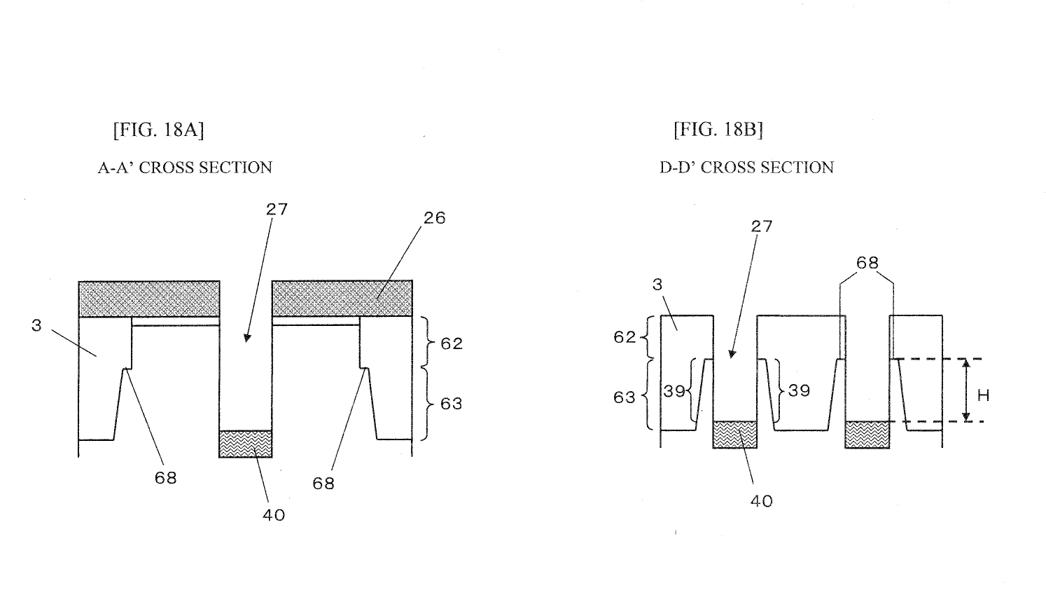

Subsequently, as illustrated in FIGS. 18A and 18B, the ion implantation method is used to dope boron at an energy of about 10 KeV with the second mask layer 6 left. A P-type impurity layer 40 is thus formed only at a bottom portion of the trench 27 for the gate electrode. The setting of the concentration of impurities in the P-type impurity layer 40 will be described below. Boron is also implanted into the surface of the isolation region 3 which is not covered with the second mask layer 6 as illustrated in FIG. 18B. However, this is not illustrated because the implanted boron exerts no effect on the operation of the transistor.

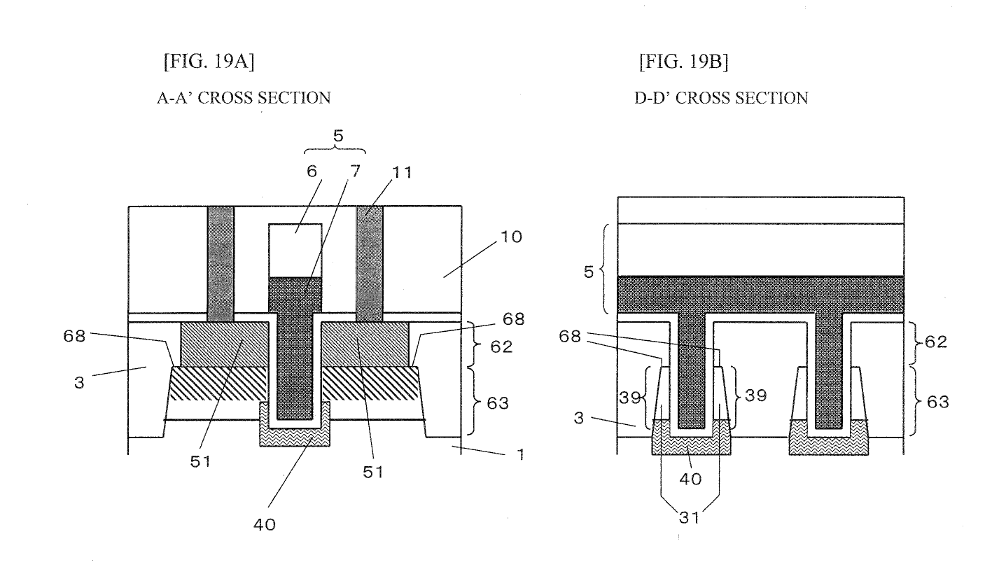

Subsequently, a semiconductor device illustrated in FIGS. 19A and 19B is finally formed using a manufacturing procedure similar to the steps illustrated in FIGS. 13A and 13B for the third exemplary embodiment and the subsequent steps. In FIGS. 19A and 19B, the components described in the third exemplary embodiment are denoted by the same reference numerals.

The boron forming the P-type impurity layer 40 diffuses and migrates under the effect of the thermal treatment performed for transistor formation. Thus, the P-type impurity layer 40 is finally positioned in the vicinity of the bottom portion of the trench 27. Consequently, in the present exemplary embodiment, as illustrated in FIG. 19B, the P-type impurity layer 31 (first impurity layer) is formed on the side portions 39 of the recess portion for the channel. The P-type impurity layer 40 (corresponding to a second impurity layer) is formed in areas located under the side portions 39 of the recess portion and at the bottom of the trench in which the polycrystalline silicon film 7 for the gate electrode is buried.

In actuality, the boundary between the P-type impurity layers 31 and 40 is not clear, with the distribution of the boron concentration varying continuously. However, the boundary is illustrated in FIGS. 19A and 19B for description. Here, for the N-channel transistor, the concentration of the P-type impurity layer 40 is set higher than that of the P-type impurity layer 31. In a specific example, when boron is implanted as impurities, the dose of ion implantation is set to about 1×10¹² ions/cm² in order to form the P-type impurity layer 31. The dose of ion implantation is set to about 1×10¹³ ions/cm² in order to form the P-type impurity layer 40. This enables the local threshold voltage of the transistor to be set lower in the area where the P-type impurity layer 31 is formed therein. In contrast, the local threshold voltage of the transistor can be set higher in the area where the P-type impurity layer 40 is formed therein.

Since the side portions 39 of the recess portion are very thin layers of thickness about 30 nm, the side portions 39 can be completely depleted while the transistor is off. Completely depleting the side portions 39 enables the transistor to be easily turned off even with a decrease in the impurity concentration of the P-type impurity layer 31. On the other hand, the area located at the bottom of the recess portion where the P-type impurity layer 40 is formed cannot be completely depleted. However, the increased threshold voltage of this area allows the transistor to be easily turned off.

Thus, the P-type impurity layer serving to control the threshold voltage of the channel area is composed of the two areas with the different concentrations. Then, for side portions 39 of the recess portion, even with the reduced concentration of the P-type impurities, the complete depletion condition can be utilized to turn off the transistor. That is, the concentration of the P-type impurity layer 31 can be set lower than that in the third exemplary embodiment independently of the area located at the bottom of the recess portion, without affecting the off property of the transistor.

This enables not only a reduction in a possible parasitic capacitance formed by the PN junction between the P-type impurity layer and the N-type diffusion layer area 9 but also relaxation of a possible electric field generated at the PN junction. As a result, a possible junction leakage current can be reduced. Therefore, an advanced transistor can be easily formed. In the fourth exemplary embodiment, the P-channel transistor can be formed as is the case with the third exemplary embodiment.

### Fifth Exemplary Embodiment

An exemplary embodiment of a semiconductor device will be described below in which the RC transistor is applied to a memory cell portion of a DRAM.

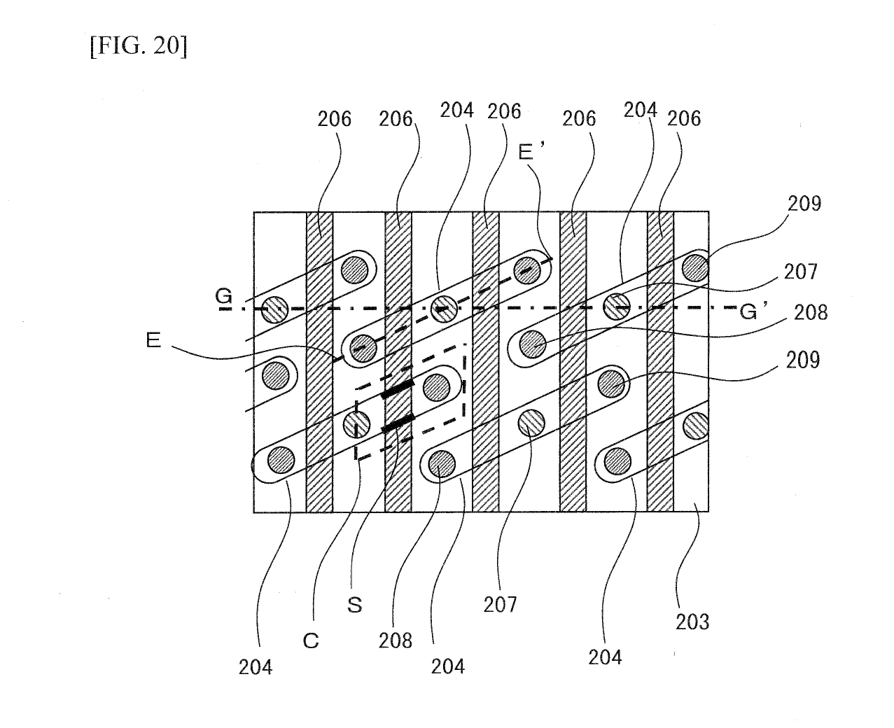

FIG. 20 is a plan view of the memory cell portion of the DRAM illustrating only parts of the memory cell portion which relate to the transistor for description.

In FIG. 20, a plurality of active areas (diffusion layer areas) 204 are regularly arranged on a semiconductor substrate (not illustrated in the drawings). The active areas 204 are partitioned by isolation regions 203. The isolation regions 203 are formed by the method illustrated above in the third exemplary embodiment. Thus, a part of a step surface in the isolation region 203 forms a top surface (not illustrated in the drawings) of each side portion of a second semiconductor area and a top surface (not illustrated in the drawings) of each of the both ends of the second semiconductor area in the extending direction.

A plurality of gate trenches 206 are arranged so as to cross the active areas 204. Each of the gate trenches 206 functions as a word line in the DRAM. Ions of impurities such as phosphorous are implanted into an area of each of the active areas 204 which is not covered with the gate trench 206 to form an N-type diffusion layer area. The N-type diffusion layer area functions as impurity diffusion layers for a source and a drain areas of the transistor and as the conductive area described in the first exemplary embodiment.

A part of FIG. 20 enclosed by a dashed line C corresponds to one RC transistor. The structure of a recess portion (not illustrated in the drawings) formed in the semiconductor substrate is inherent in the fifth exemplary embodiment as illustrated above. That is, a channel area is formed in parts of the area enclosed by the dashed line C which are illustrated by thick lines S. This also applies to the other active areas 204.

In the third and fourth exemplary embodiments, the gate trench and the active area cross at right angles. However, the RC transistor according to the fifth exemplary embodiment is applicable even to a layout in which the gate trench 206 and the active area 204 cross obliquely as shown in FIG. 20, without posing any problem. Furthermore, the RC transistor according to the fifth exemplary embodiment does not pose any problem with the manufacturing process.

A first contact plug 207 is provided in a central portion of each of the active areas 204 in contact with an N-type diffusion layer area (conductive area) on a surface of the active area 204. Second contact plugs 208 and 209 are formed at the both ends of each of the active areas 204 in contact with the N-type diffusion layer area (conductive area) on the surface of the active area 204. In spite of the different reference numerals for description, the first and second contact plugs 207, 208, and 209 can be simultaneously formed during actual manufacture.

In this layout, to allow memory cells to be densely arranged, two adjacent transistors are arranged so as to share one first contact plug 207.

In the subsequent step, a wiring layer (not illustrated in the drawings) contacting the first contact plugs 207 is formed in a direction which is illustrated by line G-G′ and which is orthogonal to the gate trenches 206. The wring layer functions as a bit line in the DRAM. Capacitor elements (not illustrated in the drawings) are connected to the respective second contact plugs 208 and 209.

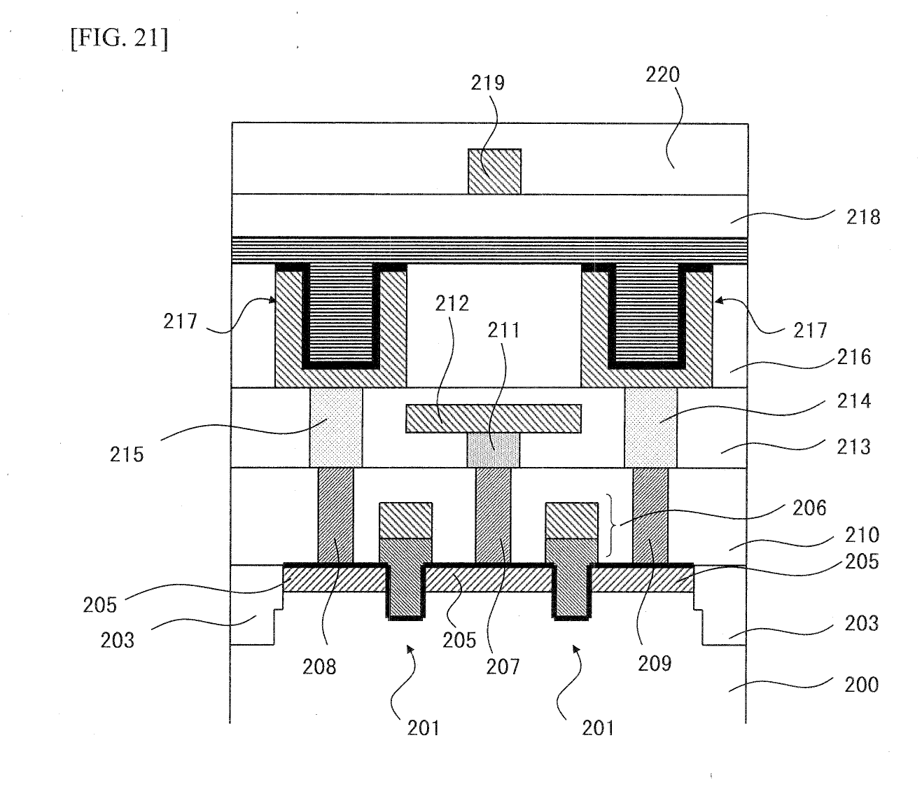

FIG. 21 shows a sectional view of a memory cell in the completed DRAM. FIG. 21 corresponds to a cross section taken along line E-E′ in FIG. 20. In FIG. 21, a semiconductor substrate made up of P-type silicon is illustrated at 200. The RC transistor according to the fifth exemplary embodiment is illustrated at 201. Since the detailed structures of the semiconductor substrate and the RC transistor have already been described, the description of the detailed structures is thus omitted. A gate trench functioning as a word line is illustrated at 206.

An N-type diffusion area 205 is formed on a surface portion of the active area 204 and is in contact with the first and second contact plugs 207, 208, and 209. Phosphorous-doped polycrystalline silicon may be used as a material for the first and second contact plugs 207, 208, and 209. A first interlayer insulating film formed on the transistor is illustrated at 210. The first contact plug 207 is connected to a wiring layer 212 functioning as a bit line, via a first contact plug 211. Tungsten may be used as a material for the wiring layer 212.

The second contact plugs 208 and 209 are connected to capacitor elements 217 via second contact plugs 215 and 214. A second interlayer insulating film, a third interlayer insulating film, and another interlayer insulating film which insulate wires are illustrated at 213, 216, and 218, respectively. Capacitor elements 217 are formed by well-known means so as to include an insulating film such as hafnium oxide (HfO) between two electrodes. An upper wiring layer formed of aluminum or the like is illustrated at 219. A surface protection film is illustrated at 220.

Turning on the RC transistor 201 allows determination, via the bit line (wiring layer 212), of whether or not charges are accumulated in the capacitor elements 217. Thus, the memory cell in the DRAM can perform an operation of storing information.

As described above, in the RC transistor according to the fifth exemplary embodiment, the side portions of the recess portion, functioning as channel areas, can be stably shaped without any variation. Consequently, a possible variation in properties among transistors can be inhibited during manufacture. Therefore, even when a large number of transistors are formed on the same semiconductor chip as in the case of the memory cells in the DRAM, the DRAM with the desired properties can be easily manufactured.

If the RC transistor illustrated in the fourth exemplary embodiment is applied to the memory cells in the DRAM, a possible leakage current in the off state can be reduced to improve the data holding property (refresh property) of the DRAM. Furthermore, the parasitic capacitance of the diffusion layer can be reduced to increase operation speed. Consequently, a high-performance DRAM can be easily manufactured.

The RC transistor according to the fifth exemplary embodiment can also be used for devices other than the memory cells in the DRAM. For example, combination with memory elements utilizing a change in resistance value instead of the capacitor elements enables formation of memory cells in a phase change memory (PRAM) or a resistance memory (ReRAM). Specifically, for the phase change memory, a memory element may be formed by well-known means using a chalcogenide material (GeSbTe or the like) with a resistance value changing consistently with the phase. The memory element may then be connected to one of the impurity diffusion layers for the source and the drain areas of the RC transistor according to the fifth exemplary embodiment, to form a memory cell. The state (resistance value) of the memory element can be determined based on the value of current flowing when the transistor is turned on.

The fifth exemplary embodiment is also applicable to semiconductor devices in general such as logic semiconductor devices with no memory cell provided that the devices use MOS transistors.

### Sixth Exemplary Embodiment

Another exemplary embodiment of the semiconductor device in which the RC transistor is applied to the memory cell portion of the DRAM will be described below.

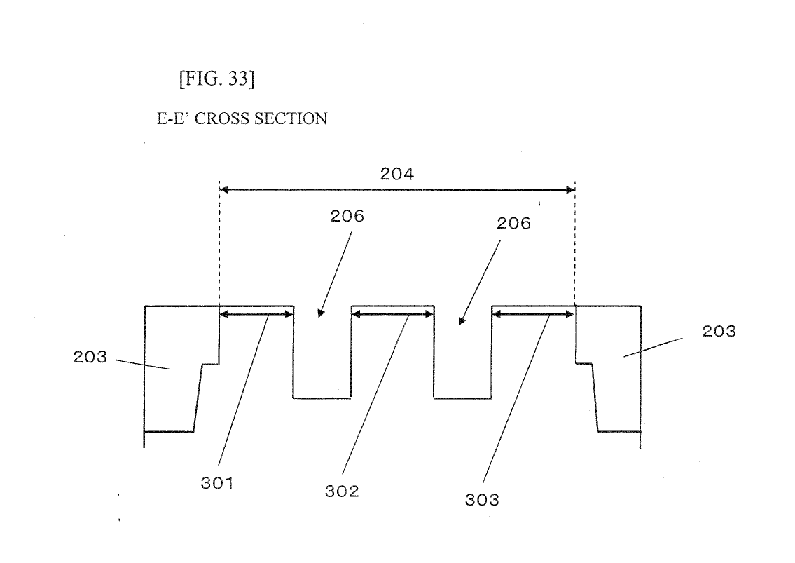

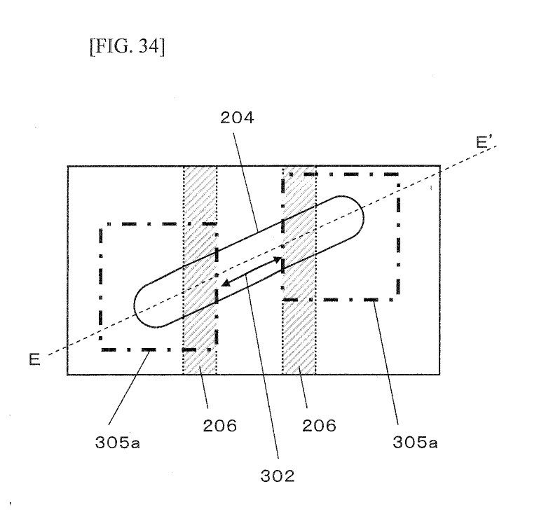

The memory cell in the DRAM illustrated in the above-described fifth exemplary embodiment is formed as is the case with the above-described third exemplary embodiment, from the beginning of the process through step (8). FIG. 33 illustrates a sectional view of the memory cell observed when step (8) is completed; the sectional view corresponds to a portion E-E′ of the plan view (FIG. 20).

The active areas 204 are partitioned by the isolation regions 203. Each of the active areas 204 is partitioned into three areas 301, 302, and 303 by the gate trenches 206. The first contact plug 207 (FIG. 20), connected to the bit line in the DRAM during the subsequent step, is formed in the central active area 302. The second contact plugs 208 and 209 (FIG. 20), connected to the capacitor elements in the DRAM during the subsequent step, are formed in the active areas 301 and 303, located at the both ends.

Then, a photo resist film is formed so as to expose the central active area 302, while covering the active areas 301 and 302, located at the both ends, and the interior of the gate trench 206, located between the active areas. FIG. 34 is a plan view illustrating only one active area 204 for simplification. An area enclosed by a dashed-dotted line 305a is covered with a photo resist film 305. A pattern of the photo resist film is also formed in another active area 204 in which a memory cell is to be formed. In each of the active areas 204 in which the memory cell is to be formed, the photo resist film may be located such that provided that the central active area 302 is exposed, the patterns of the photo resist film 305 contact each other between the adjacent active areas.

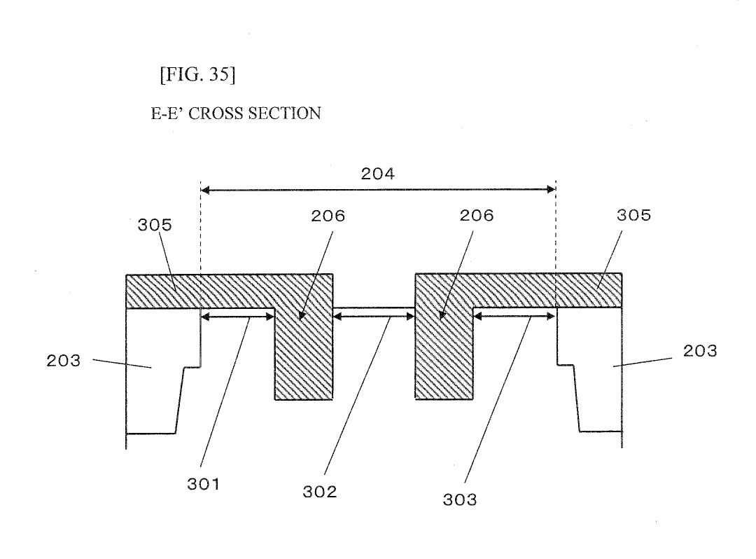

FIG. 35 illustrates a sectional view taken along line E-E′ in FIG. 34. The photo resist film 305 is formed to fill an area of the gate trench 206 which crosses the active area 204.

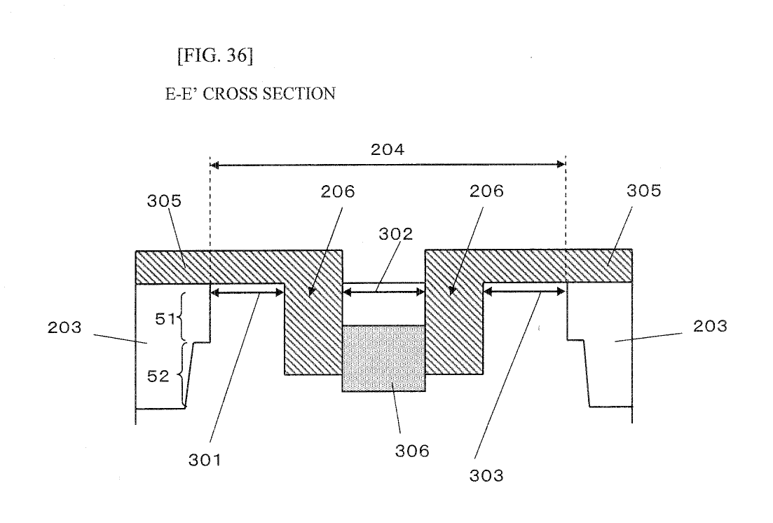

Then, as shown in FIG. 36, boron (B) ions are implanted at an energy of 30 to 70 KeV to form an impurity implantation layer 306. In the present exemplary embodiment, the impurity implantation layer 306 is formed in the part of the second semiconductor area 52 but may extend into the first semiconductor area 51 without posing any problem. The threshold voltage of the transistor forming the memory cell can be adjusted to the desired value by regulating the concentration of the boron implanted into the impurity implantation layer 306 (the dose of the ion implantation). The photo resist film 305 is removed after the ion implantation.

The RC transistor according to the sixth exemplary embodiment eliminates the need to set the impurity concentrations of whole areas in which channels are formed in the on state to an equivalent value in order to control the threshold voltage. If a relatively high threshold voltage (about 1 V) is set for transistors used in semiconductor devices like transistors used in memory cells or the like, the threshold voltage may be set higher in a part of a path including the channels formed and the flowing current. In the sixth exemplary embodiment, as illustrated in FIG. 36, the impurity implantation layer 306 for adjustment of the threshold voltage is formed only in the central area 302 of the active area 204. This can set the threshold voltage for the transistor in the memory cell to the optimum value without forming the impurity implantation layer for adjustment of the threshold voltage, in the other areas in which channels are to be formed. The effects of the transistor thus formed will be described below.

In the manufacturing method illustrated above in the third embodiment, the ion implantation for adjustment of the threshold voltage is performed so as to penetrate the polycrystalline silicon film for the gate electrode. In the sixth exemplary embodiment, before the formation of the gate insulating film, a mask formed by the photo resist film (305) is used to carry out the ion implantation step.

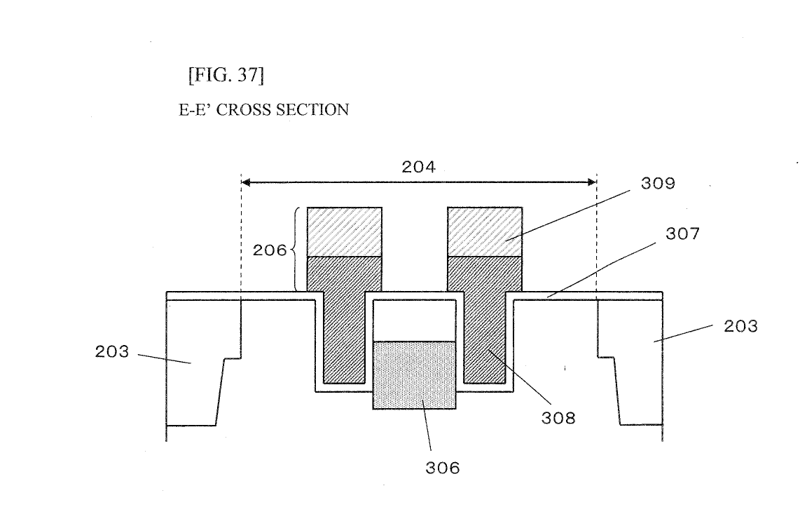

Then, as illustrated in FIG. 37, the photo resist film (305) is removed to form the gate insulating film 307 (step (9)). Subsequently, a polycrystalline silicon film 308 and a high melting-point metal film 309 are laminated to form the gate trench 206 (step (10)). The gate trench 206 functions as a word line in the DRAM.

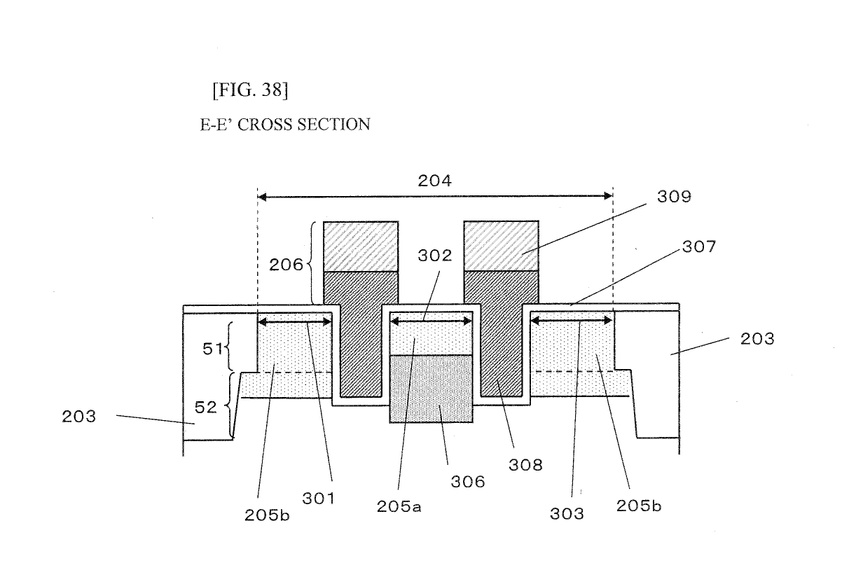

Then, as illustrated in FIG. 38, phosphorous (P) is doped into the first and second semiconductor areas 51 and 52 in the active area 204 by ion implantation. Thus, N-type diffusion layer areas 205b are formed in the areas 301 and 303, located at the both ends of the active area 204. A part of each of the N-type diffusion layer areas 205b which is positioned in the second semiconductor area functions as one of the impurity diffusion layers for the source and the drain areas. In the areas 301 and 303, located at the both ends of the active area 204, the first and second semiconductor areas 51 and 52 are of the same conductivity type.

The impurity implantation layer 306 is initially formed in the central area 302 of the active area 204. Thus, adjustment of the dose of the implantation allows an N-type diffusion layer area 205a to be finally formed in the first semiconductor area 51, with the P-type impurity implantation layer left in the second semiconductor area 52 (step (11)). A portion of the impurity implantation layer 306 overlaps the N-type diffusion layer area 205a with a conductivity type different from that of the impurity implantation layer 306. However, the overlapping portion is also changed into the N-type diffusion layer area 205a by setting the impurity concentration higher in the N-type diffusion layer area 205a than in the impurity implantation layer 306. Consequently, a PN junction is formed between the N-type impurity diffusion layer area 205a in the first semiconductor area 51 and the impurity implantation layer 306 in the second semiconductor area 52. In the present exemplary embodiment, while the transistor is on, a channel is formed in the impurity implantation layer 306. The N-type diffusion layer area 205a positioned in the first semiconductor area thus functions as one of the impurity diffusion layers for the source and the drain areas.

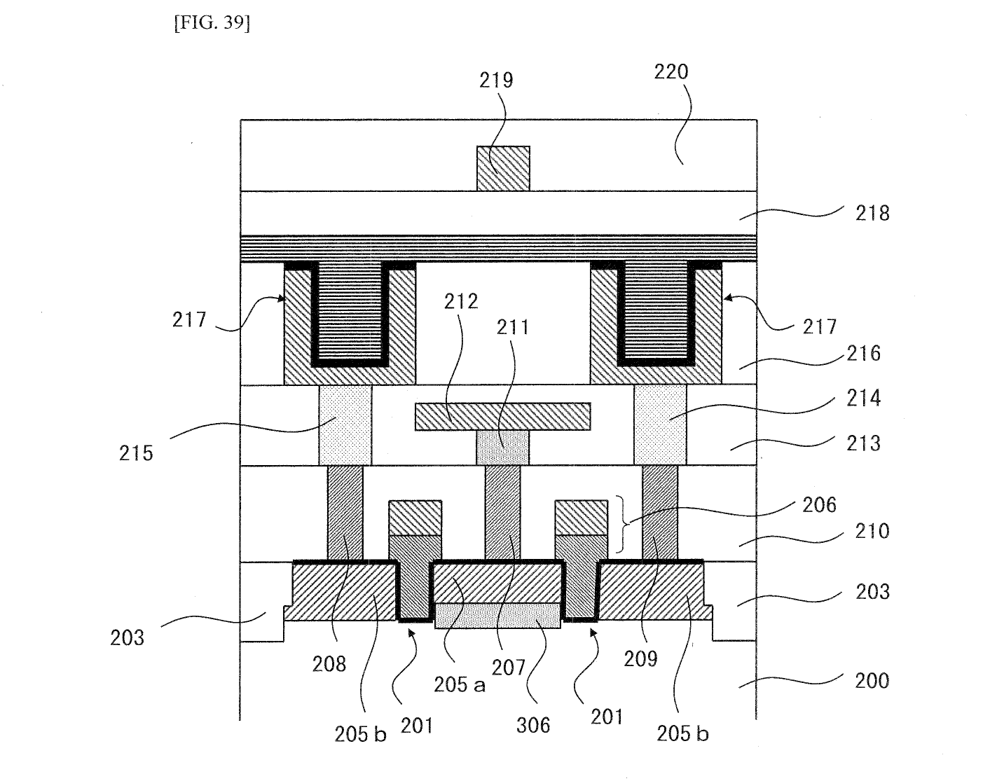

The subsequent steps are carried out as is the case with the fifth exemplary embodiment to complete the memory cell in the DRAM as illustrated in FIG. 39. In FIG. 39, the components described in the fifth exemplary embodiment are denoted by the same reference numerals. In the present exemplary embodiment, the impurity implantation layer 306 for adjustment of the threshold voltage of the transistor 201 is formed in a lower area (in the second semiconductor area) that is in contact with the N-type diffusion layer area 205a, connected to the bit line 212. The impurity diffusion layer for adjustment of the threshold voltage is not formed in a lower area (in the second semiconductor area) that is in contact with the N-type diffusion layer area 205b, connected to the capacitor element 217, a bottom surface of the gate trench, or in the side portions of the recess portion in the second semiconductor area, which lie opposite the side surfaces of the gate electrode. Thus, while the transistor is off, a possible leakage current from the PN junction of the N-type diffusion layer area 205b, connecting to the capacitor element 217, can be inhibited. This is because the avoidance of implantation of boron for adjustment of the threshold voltage reduces the concentration of impurities in the P-type impurity layer forming the PN junction with the N-type diffusion layer area 205b. This reduces the intensity of electric fields generated at the PN junction, thus resulting in reducing a possible leakage current from the PN junction.

In the sixth exemplary embodiment, in the third semiconductor areas of RC transistor, in which the impurity diffusion layers for the source and the drain areas are formed, the conductivity type of one of the areas is the same as that of the first semiconductor area, positioned over the third semiconductor area. The conductivity type of the other area is different from that of the first semiconductor area, positioned over the third semiconductor area. If the RC transistor is used for the memory cell in the DRAM, the active area side to which the bit line is connected is located such that the first and third semiconductor areas are of the different conductivity types, whereas the active area side to which the capacitor is connected is located such that the first and third semiconductor areas are of the same conductivity type. The threshold voltage of the transistor can be controlled by adjusting the concentration of impurities in the impurity implantation layer 306.

Thus, a possible leakage current from the PN junction can be inhibited in the active area to which the capacitor is connected. Consequently, charges accumulated in the capacitor elements can be inhibited from being lost in the off state. Therefore, a high-performance DRAM that is excellent in the property (refresh property) of holding stored data can be easily manufactured. Even in the RC transistor according to the present exemplary embodiment, the positions of the impurity diffusion layers for the source and the drain areas can be varied as is the case with the third exemplary embodiment.

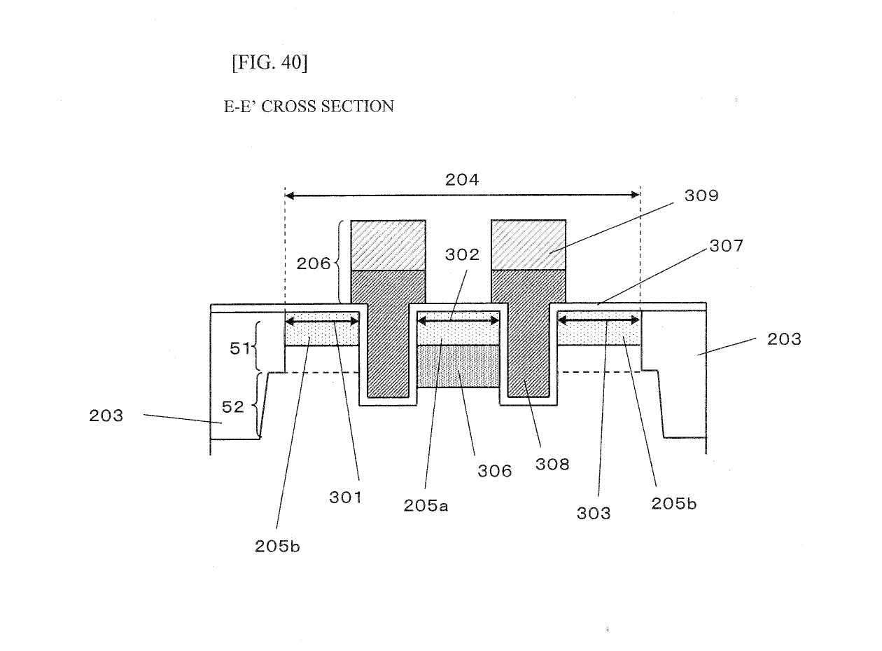

This variation is illustrated in FIG. 40 (corresponding to a cross section taken along line E-E′). The energy of the ion implantation for forming the N-type diffusion layer areas 205a and 205b is adjusted to form the N-type diffusion layer areas 205a and 205b in the upper areas of the first semiconductor areas 51. The energy of the ion implantation is similarly adjusted to form the impurity implantation layer 306 such that the layer 306 is positioned in the lower part of the first semiconductor area 51 and in the upper part of the second semiconductor area 52. Even in this variation, the threshold voltage of the transistor can be adjusted based on the concentration of the impurity implantation layer 306.

In the structure of the transistor illustrated in the variation, the recess portion of the channel area, formed opposite the lower part of the gate electrode, is not in direct contact with the N-type impurity diffusion layers 205a and 205b. Thus, even if a transistor with a short gate length is manufactured by miniaturization, the possible short channel effect can be prevented to easily control the threshold voltage.

Even if the transistor according to the variation is used for the memory cell in the DRAM, electrically connecting the N-type diffusion layer area 205b to the capacitor element allows easy manufacturing of a DRAM which is excellent in the property (refresh property) of holding stored data and which offers an increased degree of integration through miniaturization.

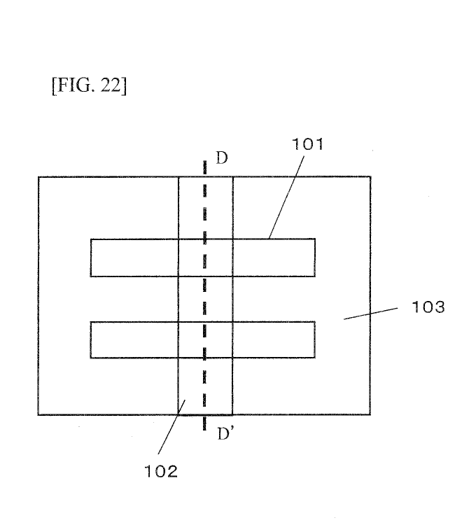

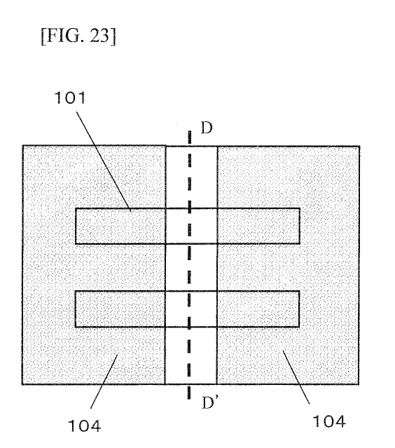

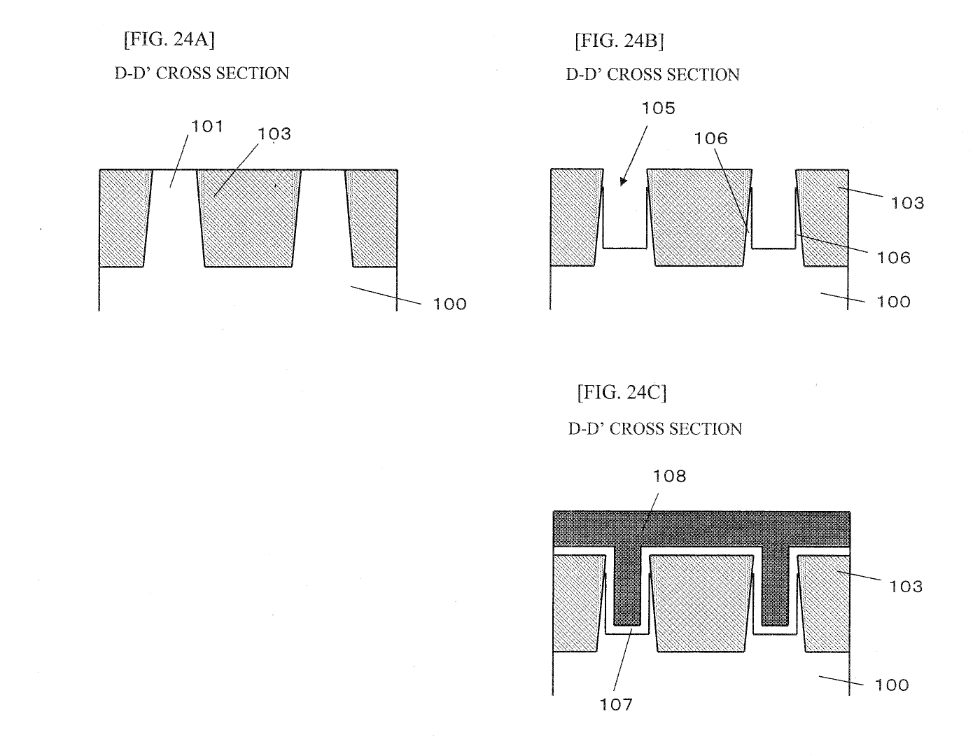

In the FIGS. 1-42, numerals have the following meanings. 1: semiconductor substrate, 2: diffusion layer region (active area), 3: isolation region, 5: gate trench, 6: low resistance conductive layer, 7: polysilicon (gate electrode), 8: gate insulating film, 9: semiconductor region, 10: interlayer insulating film, 11: contact plug, 20: silicon oxide film, 21: second mask layer 2: opening, 23: sidewall, 23a: silicon oxide film, 23b: silicon nitride film, 24: lower opening, 25: silicon oxide film, 26: silicon nitride film, 27: trench part, 30: polysilicon film, 31: impurity implantation layer, 34: opening A, 35: second semiconductor extending direction, 36: recess portion, 38: side surface of gate electrode, 39: side portion of recess portion, 40: P-type impurity layer, 42: impurity diffusion layers for source and drain areas, 43: op surface of recess portion, 45: semiconductor layer, 51: first semiconductor area, 52: second semiconductor area, 53: opening of mask layer, 54: top surface of the both ends of the second semiconductor area, 60: step surface, 61: depth direction, 62: upper isolation region, 63: lower isolation region, 63a: silicon nitride film, 63c: void, 64: semiconductor substrate, 65: step structure, 66: upper opening, 67: lower opening, 68: step surface, 69: isolation region, 80, 81, 82: silicon oxide film, 90: impurity diffusion layer, 100: semiconductor substrate, 101: diffusion layer region (active area), 102: gate trench, 103: isolation region, 104: mask layer 105: trench, 106: silicon layer, 107: gate insulating layer, 108: conductive layer, 200: semiconductor substrate, 201: RC transistor, 203: isolation region, 204: active region, 205: diffusion layer areas for source and drain areas, 206: gate trench, 207, 211: first contact plug, 208, 209, 214, 215: second contact plug, 210, 213, 216, 218: interlayer insulating film, 212: wiring layer, 217: capacitor element, 219: wiring layer, 220: surface protection film

It is apparent that the present invention is not limited to the above embodiments, but may be modified and changed without departing from the scope and spirit of the invention.

What is claimed is:

1. A semiconductor device comprising a field effect transistor comprising:
a second semiconductor area extending in a predetermined direction;
a gate electrode buried in an intermediate portion of the second semiconductor area in the predetermined direction and extending upward from the second semiconductor area;
a recess portion constituting the intermediate portion of the second semiconductor area and including side portions located opposite to each side surface of the gate electrode buried in the recess portion that are parallel to the predetermined direction;
third semiconductor areas positioned on both sides in the second semiconductor area sandwiching the recess portion in the predetermined direction;
first semiconductor areas formed on the third semiconductor areas and positioned on both sides, in the predetermined direction, sandwiching the portion of the gate electrode which extends upward from the second semiconductor area;
a gate insulating film formed between the gate electrode and both the first and second semiconductor areas; and
impurity diffusion layers for a source and a drain areas formed in the first or third semiconductor areas,
wherein top surfaces of the side portions of the recess portion are the same level as a top surface of an end portion of the second semiconductor area in the predetermined direction.

2. The semiconductor device according to claim 1, further comprising an isolation region formed so as to surround the field effect transistor,
wherein the isolation region comprises:
a step structure including a step surface that is perpendicular to a depth direction;
an upper isolation region that contacts the first semiconductor areas above the step surface; and
a lower isolation region that contacts the second semiconductor area below the step surface,
the step surface constitutes the top surfaces of the side portions of the recess portion and the top surface of the end portion of the second semiconductor area in the predetermined direction, and
a cross sectional area of the upper isolation region which is perpendicular to the depth direction is larger than a cross sectional area of the lower isolation region which is perpendicular to the depth direction.

3. The semiconductor device according to claim 2,
wherein the upper isolation region is filled with silicon oxide, and the lower isolation region is filled with material including at least silicon nitride.

4. A semiconductor device comprising an isolation region comprising: a step structure including a step surface that is perpendicular to a depth direction;
an upper isolation region located above the step surface; and
a lower isolation region located below the step surface,
wherein a cross sectional area of the upper isolation region which is perpendicular to the depth direction is larger than a cross sectional area of the lower isolation region which is perpendicular to the depth direction.

5. The semiconductor device according to claim 4, further comprising two field effect transistors isolated from each other via the isolation region,
wherein each of the two field effect transistors comprises:
a second semiconductor area extending in a predetermined direction;
a gate electrode buried in an intermediate portion of the second semiconductor area in the predetermined direction and extending upward from the second semiconductor area;
a recess portion constituting the intermediate portion of the second semiconductor area in the predetermined direction and including side portions located opposite to each side surface of the gate electrode buried in the recess portion that are parallel to the predetermined direction;
third semiconductor areas positioned on both sides in the second semiconductor area sandwiching the recess portion in the predetermined direction;
first semiconductor areas formed on the third semiconductor areas and positioned on both sides, in the predetermined direction, sandwiching the portion of the gate electrode which extends upward from the second semiconductor area;
a gate insulating film formed between the gate electrode and both the first and second semiconductor areas; and
impurity diffusion layers for a source and a drain areas formed in the first or third semiconductor areas,
wherein the side portions of the recess portion and an end portion of the second semiconductor area in the predetermined direction comprise the step surface,
the upper isolation region is disposed between the first semiconductor areas of the two field effect transistors, and
the lower isolation region is disposed between the second semiconductor areas of the two field effect transistors.

6. The semiconductor device according to claim 1,
wherein the field effect transistor further comprises a gate insulating film between a bottom surface of the gate electrode and a bottom portion of the recess portion, and
when the field effect transistor is on, a channel area is formed both immediately under the gate electrode and at the side portions of the recess portion.

7. The semiconductor device according to claim 1,
wherein height of a portion of the gate electrode opposite to the side portions of the recess portion is 30 to 60 nm.

8. The semiconductor device according to claim 1,
wherein an impurity concentration of the semiconductor area located immediately under the gate electrode is higher than an impurity concentration of the side portions of the recess portion.

9. The semiconductor device according to claim 8,
wherein height of a portion of the gate electrode opposite to the side portions of the recess portion is 90 to 110 nm.

10. The semiconductor device according to claim 1 further comprising a memory cell in addition to the field effect transistor,
wherein the memory cell comprising:
a first contact plug electrically connected to one of the source and the drain areas of the field effect transistor;
a second contact plug electrically connected to the other of the source and the drain areas of the field effect transistor,
a bit line electrically connected to the first contact plug; and
a capacitor electrically connected to the second contact plug,
wherein the semiconductor device operates as a DRAM.

11. The semiconductor device according to claim 5, further comprising memory cells in addition to the field effect transistors,
wherein each of the memory cells comprising:
a first contact plug electrically connected to one of the source and the drain areas of each field effect transistor;
a second contact plug electrically connected to the other of the source and the drain areas of each field effect transistor;
a bit line electrically connected to each first contact plug; and
a capacitor electrically connected to each second contact plug,
wherein the semiconductor device operates as a DRAM.

12. The semiconductor device according to claim 1, further comprising a storage element electrically connected to one of the source and the drain areas of the field effect transistor,
wherein the storage element holds information on the basis of a change in electric resistance value, and
the semiconductor device outputs the information by turning on the field effect transistor.

13. The semiconductor device according to claim 1,
wherein while the field effect transistor is off, the semiconductor areas in the side portions of the recess portion are completely depleted.

14. The semiconductor device according to claim 1,
wherein a threshold voltage of the semiconductor areas constituting the side portions of the recess portion is lower than a threshold voltage of a semiconductor area located immediately under the gate electrode.

15. The semiconductor device according to claim 1,
wherein the source and the drain areas are formed in the first semiconductor areas,
one of the source and the drain areas is the same conductivity type as the third semiconductor area positioned under the one of the source and the drain areas, and
the other of the source and the drain areas is a different conductivity type from the third semiconductor area positioned under the other of the source and the drain areas.

16. The semiconductor device according to claim 15,
wherein a threshold voltage of the field effect transistor is determined by the concentration of an impurity of the third semiconductor area under the other of the source and the drain areas.

17. The semiconductor device according to claim 15,
wherein the semiconductor device further comprises a capacitor, the capacitor is electrically connected to the one of the source and the drain areas having the same conductivity type as the third semiconductor area positioned under the one of the source and the drain areas,
the field effect transistor and the capacitor constitute a memory cell for a DRAM.

18. The semiconductor device according to claim 1,
wherein the impurity diffusion layers for the source and the drain areas are formed in upper areas in the first semiconductor areas.

19. The semiconductor device according to claim 18,
wherein a threshold voltage of the field effect transistor is determined by the concentration of an impurity in an area between the impurity diffusion layers for the source and the drain areas and the recess portion in the second semiconductor area.

20. The semiconductor device according to claim 18,
wherein the impurity diffusion layer used to adjust a threshold voltage of the field effect transistor is formed only under one of the impurity diffusion layers for the source and the drain areas.

21. The semiconductor device according to claim 20,
wherein the semiconductor device further comprises a capacitor, the capacitor is electrically connected to one of the source and the drain areas under which the impurity diffusion layer used to adjust the threshold voltage is not formed,
the field effect transistor and the capacitor constitute a memory cell for a DRAM.

22. The semiconductor device according to claim 1,
wherein minimum width of the side portions of the recess portion in the predetermined direction is 100 nm or less.

23. The semiconductor device according to claim 1,
wherein width of the step surface constituting the top surfaces of the side portions of the recess portion in a direction perpendicular to the predetermined direction is 10 to 50 nm.

24. A method of manufacturing a semiconductor device comprising an isolation region including a step structure including a step surface that is perpendicular to a depth direction the method comprising:
(1) forming an upper opening in a semiconductor substrate;
(2) forming an insulating film on a side wall of the upper opening;
(3) forming a lower opening under the upper opening and forming the step surface under the insulating film by etching an interior of the upper opening using the insulating film as a mask;
(4) filling an insulating material into the lower opening by a CVD method or an HDP-CVD method to form a lower isolation region; and
(5) filling an insulating material into the upper opening by the HDP-CVD method to form an upper isolation region.

25. The method of manufacturing a semiconductor device according to claim 24,
wherein step (1) comprises:
(1-1) forming a first insulating layer and a first mask layer on the semiconductor substrate in this order; and
(1-2) etching the first insulating layer and the semiconductor substrate using the first mask layer as a mask, to form two or more protruding first semiconductor areas extending in a predetermined direction and the upper opening located between the first semiconductor areas, under the first mask layer,
step (2) comprises:
forming a side wall on side surfaces of each of the protruding first semiconductor areas as the insulating film, and
step (3) comprises:
etching the semiconductor substrate using the first mask layer and the side wall as a mask to form second semiconductor areas extending under the respective first semiconductor areas in the predetermined direction and the lower opening located between the second semiconductor areas.

26. The method of manufacturing a semiconductor device according to claim 25,
wherein step (1-2) comprises using a mixed gas containing chloride (Cl₂), hydrogen bromide (HBr), and oxygen (O₂) to etch the semiconductor substrate under a condition with an atmosphere at a pressure of 10 to 50 mTorr.

27. The method of manufacturing a semiconductor device according to claim 25, after step (5), further comprising:
(6) removing the first mask layer and then forming a second mask layer comprising openings on an intermediate portion of each of the first semiconductor areas in the predetermined direction;
(7) anisotropically etching the first insulating layer and the first and second semiconductor areas using the second mask layer and the side wall as a mask, to form openings A and recess portions comprising side portions including the step surface as a top surface, in intermediate portions of each of the first and second semiconductor areas in the predetermined direction, respectively;
(8) removing the second mask layer;
(9) forming a gate insulating film on inner walls of each of the openings A and the recess portions;
(10) forming a gate electrode in each of the openings A and the recess portions;
(11) implanting a channel impurity into the first semiconductor areas; and
(12) forming impurity diffusion layers for a source and a drain areas by implanting an impurity into the first semiconductor areas, to form two or more field effect transistors.

28. The method of manufacturing a semiconductor device according to claim 25, after step (5), further comprising:
(6) removing the first mask layer and then forming a second mask layer comprising openings on an intermediate portion of each of the first semiconductor areas in the predetermined direction;
(7) anisotropically etching the first insulating layer and the first and second semiconductor areas using the second mask layer and the side wall as a mask, to form openings A and recess portions comprising side portions including the step surface as a top surface, in intermediate portions of each of the first and second semiconductor areas in the predetermined direction, respectively;
(8) removing the second mask layer;
(9) forming a gate insulating film on inner walls of each of the openings A and the recess portions;
(10) forming a gate electrode in each of the openings A and the recess portions;
(11) implanting a channel impurity into the second semiconductor areas; and
(12) forming impurity diffusion layers for a source and a drain areas by implanting an impurity into the third semiconductor areas positioned on both sides in each of the second semiconductor areas sandwiching the recess portion in the predetermined direction, to form two or more field effect transistors.

29. The method of manufacturing a semiconductor device according to claim 27, after step (12), further comprising:
forming a first interlayer insulating film all over a surface of the field effect transistors;
forming a first contact plug and a second contact plug in the first interlayer insulating film so that the first contact plug is electrically connected to one of the source and the drain areas of each of the field effect transistors and the second contact plug is electrically connected to the other of the source and the drain areas of each of the field effect transistors;
forming a second interlayer insulating film all over a surface of the first interlayer insulating film;
forming a bit line in the second interlayer insulating film so that the bit line is electrically connected to the first contact plug, and extending the second contact plug in the first interlayer insulating film, into the second interlayer insulating film;
forming a third interlayer insulating film all over a surface of the second interlayer insulating film; and
forming a capacitor electrically connected to the second contact plug, in the third interlayer insulating film.

30. The method of manufacturing a semiconductor device according to claim 28, after step (12), further comprising:
forming a first interlayer insulating film all over a surface of the field effect transistors;
forming a first contact plug and a second contact plug in the first interlayer insulating film so that the first contact plug is electrically connected to one of the source and the drain areas of each of the field effect transistors and the second contact plug is electrically connected to the other of the source and the drain areas of each of the field effect transistors;
forming a second interlayer insulating film all over a surface of the first interlayer insulating film;
forming a bit line in the second interlayer insulating film so that the bit line is electrically connected to the first contact plug, and extending the second contact plug in the first interlayer insulating film, into the second interlayer insulating film;
forming a third interlayer insulating film all over a surface of the second interlayer insulating film; and
forming a capacitor electrically connected to the second contact plug, in the third interlayer insulating film.

31. The method of manufacturing a semiconductor device according to claim 24,
wherein in step (4), the insulating material filled into the lower opening contains at least silicon nitride.
